(19) United States
(12) Patent Application Publication
(10) Pub. No.: US 2016/0006433 A1
(43) Pub. Date: Jan. 7, 2016

(54) SEMICONDUCTOR DEVICE AND ELECTRONIC DEVICE

(71) Applicant: Semiconductor Energy Laboratory Co.,Ltd., Atsugi-shi (JP)

(72) Inventors: Takahiko ISHIZU, Atsugi (JP); Wataru UESUGI, Atsugi (JP)

(21) Appl. No.: 14/755,906

(22) Filed: Jun. 30, 2015

(30) Foreign Application Priority Data
Jul. 4, 2014 (JP) 2014-138493

(51) Int. Cl. H03K 17/687

(52) U.S. Cl. CPC H03K 17/687

(57) ABSTRACT

A semiconductor device with a novel structure is provided. In the semiconductor device executing a pipeline processing, a first arithmetic unit and a second arithmetic unit are provided for an execution stage, and transistors for performing power gating for the respective arithmetic units are provided. Only the arithmetic unit that performs an arithmetic operation is supplied with power supply voltage. Thus, fine-grained power gating can be performed, so that the power consumption of the semiconductor device can be reduced. In each of the transistors for performing power gating, a channel formation region includes an oxide semiconductor; thus, a reduction in leakage current between power supply lines can be achieved. Furthermore, these transistors and transistors in the arithmetic units can be provided in different layers, and thus an increase in area overhead due to the additionally provided transistors can be prevented.

### BACKGROUND OF THE INVENTION

1. Field of the Invention

One embodiment of the present invention relates to a semiconductor device.

Note that one embodiment of the present invention is not limited to the above technical field. The technical field of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, a method for driving any of them, and a method for manufacturing any of them.

2. Description of the Related Art

The technical development of a semiconductor device that can hold charges corresponding to data by using a transistor including an oxide semiconductor in its channel formation region (OS transistor) and a transistor including silicon in its channel formation region (Si transistor) in combination has been progressing (for example, see Patent Document 1).

### REFERENCE

### Patent Document

[Patent Document] Japanese Published Patent Application No. 2013-9297

### SUMMARY OF THE INVENTION

An object of one embodiment of the present invention is to provide a novel semiconductor device or the like.

Another object of one embodiment of the present invention is to provide a novel semiconductor device or the like in which an increase in circuit area is prevented and a reduction in power consumption can be achieved by performing fine-grained power gating. Another object of one embodiment of the present invention is to provide a novel semiconductor device or the like in which design efficiency is improved.

Note that objects of one embodiment of the present invention are not limited to the aforementioned objects. The objects described above do not disturb the existence of other objects. The other objects are the ones that are not described above and will be described below. The other objects will be apparent from and can be derived from the description of the specification, the drawings, and the like by those skilled in the art. One embodiment of the present invention solves at least one of the aforementioned objects and the other objects.

One embodiment of the present invention is a semiconductor device executing a pipeline processing, including a first arithmetic portion and a second arithmetic portion in an execution stage for executing the pipeline processing. The first arithmetic portion includes a first arithmetic unit and a first transistor. The first transistor is between wirings through which power supply voltage is supplied to the first arithmetic unit. The first transistor is configured to stop supply of the power supply voltage to the first arithmetic unit by being off. The second arithmetic portion includes a second arithmetic unit and a second transistor. The second transistor is between the wirings through which the power supply voltage is supplied to the second arithmetic unit. The second transistor is configured to stop the supply of the power supply voltage to the second arithmetic unit by being off. The first transistor and the second transistor are controlled to be off in response to an instruction decoded in a decoder.

Another embodiment of the present invention is a semiconductor device executing a pipeline processing, including a first arithmetic portion and a second arithmetic portion in an execution stage for executing the pipeline processing. The first arithmetic portion includes a first arithmetic unit and a first transistor. The first transistor is between wirings through which power supply voltage is supplied to the first arithmetic unit. The first transistor is configured to stop supply of the power supply voltage to the first arithmetic unit by being off. The second arithmetic portion includes a second arithmetic unit and a second transistor. The second transistor is between the wirings through which the power supply voltage is supplied to the second arithmetic unit. The second transistor is configured to stop the supply of the power supply voltage to the second arithmetic unit by being off. The first arithmetic unit and the second arithmetic unit include a third transistor. The first transistor and the second transistor are controlled to be off in response to an instruction decoded in a decoder. The first transistor and the second transistor are provided in a layer which is different from a layer in which the third transistor is provided.

In the semiconductor device of one embodiment of the present invention, the third transistor is preferably a transistor in which a channel formation region includes silicon.

In the semiconductor device of one embodiment of the present invention, in each of the first transistor and the second transistor, a channel formation region preferably includes an oxide semiconductor. The oxide semiconductor preferably contains In, Ga, and Zn.

In the semiconductor device of one embodiment of the present invention, a source electrode or a drain electrode of the third transistor preferably has a region overlapping with a source electrode or a drain electrode of the first transistor or the second transistor.

Note that other embodiments of the present invention will be described in the following embodiments and the drawings.

According to one embodiment of the present invention, a semiconductor device or the like with a novel structure can be provided.

Further, according to one embodiment of the present invention, a novel semiconductor device or the like in which an increase in circuit area is prevented and a reduction in power consumption can be achieved by performing fine-grained power gating can be provided. Furthermore, according to one embodiment of the present invention, a novel semiconductor device or the like in which design efficiency is improved can be provided.

Note that the description of these effects does not disturb the existence of other effects. One embodiment of the present invention does not necessarily have all of these effects. Other effects will be apparent from and can be derived from the description of the specification, the drawings, the claims, and the like.

### BRIEF DESCRIPTION OF THE DRAWINGS

FIG. 1 illustrates a configuration example of a semiconductor device.

FIGS. 2A and 2B illustrate a configuration example of a semiconductor device.

FIGS. 3A and 3B illustrate a configuration example of a semiconductor device.

FIGS. 4A and 4B each illustrate a configuration example of a semiconductor device.

FIGS. 5A and 5B each illustrate a configuration example of a semiconductor device.

FIGS. 6A and 6B each illustrate a configuration example of a semiconductor device.

FIGS. 7A, 7B-1, and 7B-2 illustrate configuration examples of a semiconductor device.

FIG. 8 illustrates a cross-sectional structure of a semiconductor device.

FIG. 9 illustrates a configuration example of a semiconductor device.

FIGS. 10A and 10B each illustrate a configuration example of a semiconductor device.

FIGS. 11A and 11B each illustrate a configuration example of a semiconductor device.

FIGS. 12A to 12C illustrate a structure of a transistor.

FIGS. 13A to 13C illustrate a structure of a transistor.

FIGS. 14A and 14B illustrate a chip and a module.

FIGS. 15A to 15F illustrate electronic devices.

FIGS. 16A to 16C illustrate a structure of a transistor.

FIGS. 17A to 17C each illustrate a configuration example of a semiconductor device.

FIGS. 18A and 18B illustrate a configuration example of a semiconductor device.

### DETAILED DESCRIPTION OF THE INVENTION

Embodiments will be described below with reference to drawings. The embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

Note that one embodiment of the present invention includes, in its category, semiconductor devices in which power gating is performed, such as an integrated circuit, an RF tag, and a semiconductor display device. The integrated circuits include, in its category, large scale integrated circuits (LSIs) including a microprocessor, an image processing circuit, a digital signal processor (DSP), and a microcontroller, and programmable logic devices (PLDs) such as a field programmable gate array (FPGA) and a complex PLD (CPLD). The semiconductor display device includes the following in its category: liquid crystal display devices, light-emitting devices in which a light-emitting element typified by an organic light-emitting diode (OLED) is provided in each pixel, electronic paper, digital micromirror devices (DMDs), plasma display panels (PDPs), field emission displays (FEDs), and other semiconductor display devices.

In the drawings, the size, the layer thickness, or the region is exaggerated for clarity in some cases. Therefore, embodiments of the present invention are not limited to such a scale. Note that the drawings are schematic views showing ideal examples, and embodiments of the present invention are not limited to shapes or values shown in the drawings. For example, the following can be included: variation in signal, voltage, or current due to noise or difference in timing.

In this specification and the like, a transistor is an element having at least three terminals: a gate, a drain, and a source. The transistor includes a channel region between the drain (a drain terminal, a drain region, or a drain electrode) and the source (a source terminal, a source region, or a source electrode) and current can flow through the drain, the channel region, and the source.

Here, since the source and the drain of the transistor change depending on the structure, the operating condition, and the like of the transistor, it is difficult to define which is a source or a drain. Thus, a portion that functions as a source or a portion that functions as a drain is not referred to as a source or a drain in some cases. Instead, one of the source and the drain might be referred to as a first electrode, and the other of the source and the drain might be referred to as a second electrode.

Note that in this specification, ordinal numbers such as “first”, “second”, and “third” are used in order to avoid confusion among components, and thus do not limit the number of the components.

In this specification, the expression “A and B are connected” means the case where A and B are electrically connected to each other in addition to the case where A and B are directly connected to each other. Here, the expression “A and B are electrically connected” means the case where electric signals can be transmitted and received between A and B when an object having any electric action exists between A and B.

The expressions include, for example, “X, Y, a source (or a first terminal or the like) of a transistor, and a drain (or a second terminal or the like) of the transistor are electrically connected to each other, and X the source (or the first terminal or the like) of the transistor, the drain (or the second terminal or the like) of the transistor, and Y are electrically connected to each other in this order”, “a source (or a first terminal or the like) of a transistor is electrically connected to X a drain (or a second terminal or the like) of the transistor is electrically connected to Y, and X the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path”. It is also possible to use the expression “a source (or a first terminal or the like) of a transistor is electrically connected to X through at least Z1 on a first connection path, the first connection path does not include a second connection path, the second connection path includes a connection path through the transistor, a drain (or a second terminal or the like) of the transistor is electrically connected to Y through at least Z2 on a third connection path, and the third connection path does not include the second connection path”. Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit structure is defined by an expression similar to the above examples, a source (or a first terminal or the like) and a drain (or a second terminal or the like) of a transistor can be distinguished from each other to specify the technical scope.

Note that these expressions are examples and the expression is not limited to these examples. Here, X, Y, Z1, and Z2 each denote an object (e.g., a device, an element, a circuit, a wiring, an electrode, a terminal, a conductive layer, and a layer).

Note that in this specification, terms for describing arrangement, such as “over” and “under”, are used for convenience to describe the positional relation between components with reference to drawings. Further, the positional relation between components is changed as appropriate in accordance with a direction in which each component is described. Thus, the positional relation is not limited to that described with a term used in this specification and can be explained with another term as appropriate depending on the situation.

The positional relation of circuit blocks in a block diagram is specified for description. Even when a block diagram shows that different functions are achieved by different circuit blocks, one circuit block may be actually configured to achieve the different functions. Functions of circuit blocks in a diagram are specified for description, and even when a diagram shows one circuit block performing given processing, a plurality of circuit blocks may be actually provided to perform the processing.

In this specification, the term “parallel” indicates that the angle formed between two straight lines is greater than or equal to −10° and less than or equal to 10°, and accordingly also includes the case where the angle is greater than or equal to −5° and less than or equal to 5°. The term “perpendicular” indicates that the angle formed between two straight lines is greater than or equal to 80° and less than or equal to 100°, and accordingly also includes the case where the angle is greater than or equal to 85° and less than or equal to 95°.

In this specification, trigonal and rhombohedral crystal systems are included in a hexagonal crystal system.

Note that the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

### Embodiment 1

In this embodiment, configuration examples of a semiconductor device will be described.

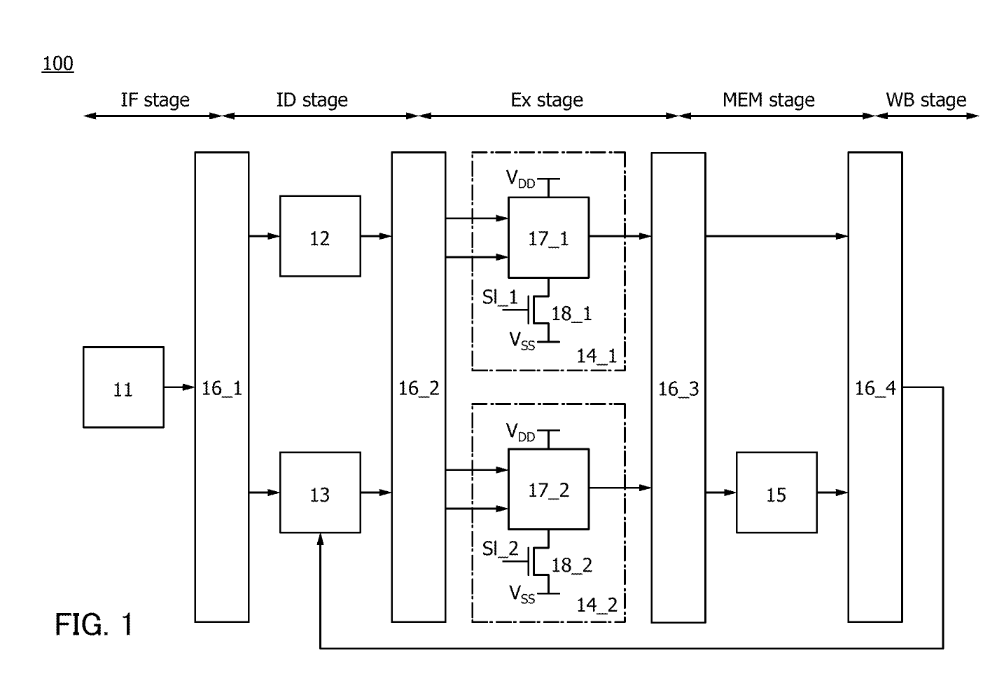

An example of the configuration of the semiconductor device of one embodiment of the present invention is illustrated in FIG. 1. A semiconductor device 100 illustrated in FIG. 1 includes an instruction memory 11, a decoder 12, a register file 13, an arithmetic portion 14_1, an arithmetic portion 14_2, a data memory 15, and pipeline registers 16_1 to 16_4.

The arithmetic portion 14_1 includes an arithmetic unit 17_1 and a transistor 18_1. The arithmetic portion 14_2 includes an arithmetic unit 17_2 and a transistor 18_2. The arithmetic unit 17_1, the transistor 18_1, the arithmetic portion 17_2, and the transistor 18_2 are provided between wirings through which power supply voltage is supplied. As the power supply voltage, a potential V_{DD} and a potential V_{SS} (V_{DD}>V_{SS}) are supplied. The arithmetic unit 17_1 is also referred to as a first arithmetic unit, and the arithmetic unit 17_2 is also referred to as a second arithmetic unit. Note that an example of using two arithmetic portions is described in this embodiment; however, in an actual circuit configuration, three or more arithmetic portions may be provided.

The on/off state of the transistor 18_1 is controlled by a control signal S1_1, and the on/off state of the transistor 18_2 is controlled by a control signal S1_2. By controlling the on/off states of the transistor 18_1 and the transistor 18_2, electrical connection between the wirings through which the power supply voltage is supplied can be changed; thus, whether the power supply voltage is supplied to the arithmetic unit 17_1 and the arithmetic unit 17_2 can be controlled.

Note that each of the arithmetic units 17_1 and 17_2 functions as a combination circuit that performs a variety of arithmetic operations such as four arithmetic operations and logic operations. As the arithmetic unit, an arithmetic logic unit (ALU) may be used for addition or subtraction, and a multiplier (abbreviated to MULT in some cases) may be used for multiplication, for example.

Note that the semiconductor device 100 illustrated in FIG. 1 is a circuit having a function of executing a pipeline processing. In FIG. 1, circuit blocks separated by the pipeline registers 16_1 to 16_4 respectively correspond to an instruction fetch stage (IF stage), an instruction decode stage (ID stage), an execution stage (Ex stage), a memory access stage (MEM stage), and a write back stage (WB stage). In each stage, transfer of data to the next stage is controlled in response to a clock.

In the semiconductor device having a function of executing a pipeline processing in FIG. 1, the pipeline registers 16_1 to 16_4 for separating the stages are provided so that a five-stage pipeline processing is executed; however, there is no particular limitation on the number of stages in the pipeline processing. Note that another architecture such as a superscalar architecture may also be used in combination with the configuration of one embodiment of the present invention.

In the semiconductor device that executes the pipeline processing in one embodiment of the present invention, the arithmetic units 17_1 and 17_2 are provided for the execution stage, to which, respectively, the transistors 18_1 and 18_2 for performing power gating are connected. Here, only the arithmetic unit that performs an arithmetic operation is supplied with the power supply voltage. Thus, fine-grained power gating can be performed, so that the power consumption of the semiconductor device can be reduced. In each of the transistors 18_1 and 18_2, a channel formation region includes an oxide semiconductor; thus, a reduction in leakage current between power supply lines can be achieved. Furthermore, these transistors and transistors in the arithmetic units can be provided in different layers, and thus an increase in area overhead due to the additionally provided transistors can be prevented.

The instruction memory 11 stores an instruction to be executed in the semiconductor device 100. The stored instruction is held in the pipeline register 16_1, and then transferred from the instruction fetch stage to the instruction decode stage in response to a clock.

The decoder 12 decodes the instruction to be executed in the semiconductor device 100. Data for performing an arithmetic operation is determined in response to the decoded instruction. Data for performing the arithmetic operation is output from the decoder 12 and/or the register file 13, held in the pipeline register 16_2, and then transferred from the instruction decode stage to the execution stage in response to a clock.

In the execution stage for which the arithmetic portion 14_1 and the arithmetic portion 14_2 are provided, the arithmetic unit in one of the arithmetic portion 14_1 and the arithmetic portion 14_2 is used for the arithmetic operation in response to the instruction decoded in the instruction decode stage. Data obtained from the arithmetic operation is held in the pipeline register 16_3, and then transferred from the execution stage to the memory access stage in response to a clock. For example, in the case where the arithmetic unit 17_1 and the arithmetic unit 17_2 are an ALU and a MULT respectively and addition is to be performed in response to an instruction, the ALU, that is, the arithmetic unit 17_1 is used for an arithmetic operation. In this case, the MULT, that is, the arithmetic unit 17_2 or another arithmetic unit is in an idle state.

In the semiconductor device of FIG. 1, two arithmetic portions, that is, the arithmetic portion 14_1 and the arithmetic portion 14_2 are illustrated; however, three or more arithmetic portions may be provided. Also in the configuration including three or more arithmetic portions, transistors may be provided for the respective arithmetic units in the arithmetic portions; thus, only the arithmetic unit that performs an arithmetic operation may be supplied with the power supply voltage so that fine-grained power gating can be performed.

The data memory 15 stores data obtained from the arithmetic operation. For the data memory 15, for example, a circuit such as a register or an SRAM can be used. Data stored in the data memory 15 or data transferred directly from the execution stage is held in the pipeline register 16_4 and then transferred from the memory access stage to the write back stage in response to a clock.

In the write back stage, the transferred data is stored in the register file 13 provided for the instruction decode stage.

The functions of the circuit blocks and the stages illustrated in FIG. 1 are examples for describing one embodiment of the present invention. Note that in the configuration of the semiconductor device in FIG. 1, for example, a control circuit for controlling the circuit block, a path through which data and an instruction are transferred to/from an external memory circuit, and the like are not illustrated.

In the semiconductor device 100 of FIG. 1, the arithmetic unit which does not perform an arithmetic operation in the arithmetic portion is in an idle state in the execution stage. For the arithmetic unit which does not perform an arithmetic operation, power gating is performed; thus, the power consumption of the semiconductor device 100 can be reduced.

The transistors in the arithmetic units 17_1 and 17_2 and the transistors 18_1 and 18_2 for performing power gating are provided in different layers. With such a configuration, an increase in circuit area can be prevented even when the transistors for performing power gating are additionally provided.

As the transistors in the arithmetic units 17_1 and 17_2, a transistor in which silicon is used for a channel formation region (Si transistor) is preferably used. Furthermore, as the transistors 18_1 and 18_2, a transistor in which an oxide semiconductor is used for a channel formation region (OS transistor) is preferably used.

In particular, silicon having crystallinity is preferably used for a Si transistor. For example, microcrystalline silicon, polycrystalline silicon, single crystal silicon, or the like is preferably used. In particular, single crystal silicon has higher field-effect mobility and higher reliability than polycrystalline silicon or amorphous silicon.

An OS transistor is preferable because off-state current can be extremely low by reducing the impurity concentration in an oxide semiconductor to make the oxide semiconductor intrinsic or substantially intrinsic. With the use of an OS transistor with low off-state current as the transistor 18_1 and the transistor 18_2 for performing power gating, leakage current flowing between power supply lines in power gating can be extremely low; thus, the power consumption of the semiconductor device can be reduced.

Unless otherwise specified, the off-state current in this specification refers to a drain current of a transistor in the off state (also referred to as non-conduction state and cutoff state). Unless otherwise specified, the off state of an n-channel transistor means that the voltage between its gate and source (Vgs: gate-source voltage) is lower than the threshold voltage Vth, and the off state of a p-channel transistor means that the gate-source voltage Vgs is higher than the threshold voltage Vth. For example, the off-state current of an n-channel transistor sometimes refers to a drain current that flows when the gate-source voltage Vgs is lower than the threshold voltage Vth.

The off-state current of a transistor depends on Vgs in some cases. For this reason, when there is Vgs at which the off-state current of a transistor is lower than or equal to I, it may be said that the off-state current of the transistor is lower than or equal to I. The off-state current of a transistor may refer to off-state current at given Vgs, off-state current at Vgs in a given range, or off-state current at Vgs at which sufficiently low off-state current is obtained.

As an example, the assumption is made of an n-channel transistor where the threshold voltage Vth is 0.5 V and the drain current is 1×10⁻⁹ A at Vgs of 0.5 V, 1×10⁻¹³ A at Vgs of 0.1 V, 1×10⁻¹⁹ A at Vgs of −0.5 V, and 1×10⁻²² A at Vgs of −0.8 V. The drain current of the transistor is 1×10⁻¹⁹ A or lower at Vgs of −0.5 V or at Vgs in the range of −0.8 V to −0.5 V; therefore, it can be said that the off-state current of the transistor is 1×10⁻¹⁹ A or lower. Since there is Vgs at which the drain current of the transistor is 1×10⁻²² A or lower, it may be said that the off-state current of the transistor is 1×10⁻²² A or lower.

In this specification, the off-state current of a transistor with a channel width W is sometimes represented by a current value in relation to the channel width W or by a current value per given channel width (e.g., 1 μm). In the latter case, the unit of off-state current may be represented by current per length (e.g., A/μm).

The off-state current of a transistor depends on temperature in some cases. Unless otherwise specified, the off-state current in this specification may be an off-state current at room temperature, 60° C., 85° C., 95° C., or 125° C. Alternatively, the off-state current may be an off-state current at a temperature at which the reliability of a semiconductor device or the like including the transistor is ensured or a temperature at which the semiconductor device or the like is used (e.g., temperature in the range of 5° C. to 35° C.). When there is Vgs at which the off-state current of a transistor at room temperature, 60° C., 85° C., 95° C., 125° C., a temperature at which the reliability of a semiconductor device or the like including the transistor is ensured, or a temperature at which the semiconductor device or the like is used (e.g., temperature in the range of 5° C. to 35° C.) is lower than or equal to I, it may be said that the off-state current of the transistor is lower than or equal to I.

The off-state current of a transistor depends on voltage Vds between its drain and source in some cases. Unless otherwise specified, the off-state current in this specification may be an off-state current at Vds with an absolute value of 0.1 V, 0.8 V, 1 V, 1.2 V, 1.8 V, 2.5 V, 3 V, 3.3 V, 10 V, 12 V, 16 V, or 20 V. Alternatively, the off-state current may be an off-state current at Vds at which the reliability of a semiconductor device or the like including the transistor is ensured or Vds used in the semiconductor device or the like. When there is Vgs at which the off-state current of a transistor is lower than or equal to I at given Vds, it may be said that the off-state current of the transistor is lower than or equal to I. Here, given Vds is, for example, 0.1 V, 0.8 V, 1 V, 1.2 V, 1.8 V, 2.5 V, 3 V, 3.3 V, 10 V, 12 V, 16 V, 20 V, Vds at which the reliability of a semiconductor device or the like including the transistor is ensured, or Vds used in the semiconductor device or the like.

In the above description of off-state current, a drain may be replaced with a source. That is, the off-state current sometimes refers to a current that flows through a source of a transistor in the off state.

In this specification, the term “leakage current” sometimes expresses the same meaning as off-state current.

In this specification, the off-state current sometimes refers to a current that flows between a source and a drain when a transistor is off, for example.

Note that a transistor in which a channel formation region includes an oxide semiconductor is used as each of the transistor 18_1 and the transistor 18_2 as one example; however, one embodiment of the present invention is not limited thereto. The transistor 18_1 and the transistor 18_2 in one embodiment of the present invention may include another semiconductor material as long as the off-state current of the transistor 18_1 and the transistor 18_2 is low. For example, an amorphous semiconductor, a microcrystalline semiconductor, a polycrystalline semiconductor, or the like may be used for a semiconductor layer. For example, amorphous silicon, microcrystalline germanium, polycrystalline silicon, or the like may be used. For example, depending on cases or conditions, silicon, germanium, silicon germanium, silicon carbide, gallium arsenide, aluminum gallium arsenide, indium phosphide, gallium nitride, an organic semiconductor, or the like may be used.

The Si transistor and the OS transistor can be stacked with an interlayer insulating layer therebetween to be provided in different layers. Consequently, area overhead can be reduced compared with the case where the Si transistors are used as the transistor 18_1 and the transistor 18_2 for performing power gating. Furthermore, finer-grained power gating can be performed per circuit block because area overhead can be reduced; thus, power gating can be performed per small circuit block such as an arithmetic unit.

An OS transistor for power gating can be provided for a fine-grained circuit block such as a standard cell that forms an arithmetic unit. For this reason, logic synthesis based on functions of an arithmetic unit can be performed with a circuit configuration including a combination circuit that forms an arithmetic unit and a transistor for power gating as a standard cell. In this case, design simplification can be achieved compared with the case where, after logic synthesis, a circuit configuration of transistors for power gating is further taken into consideration.

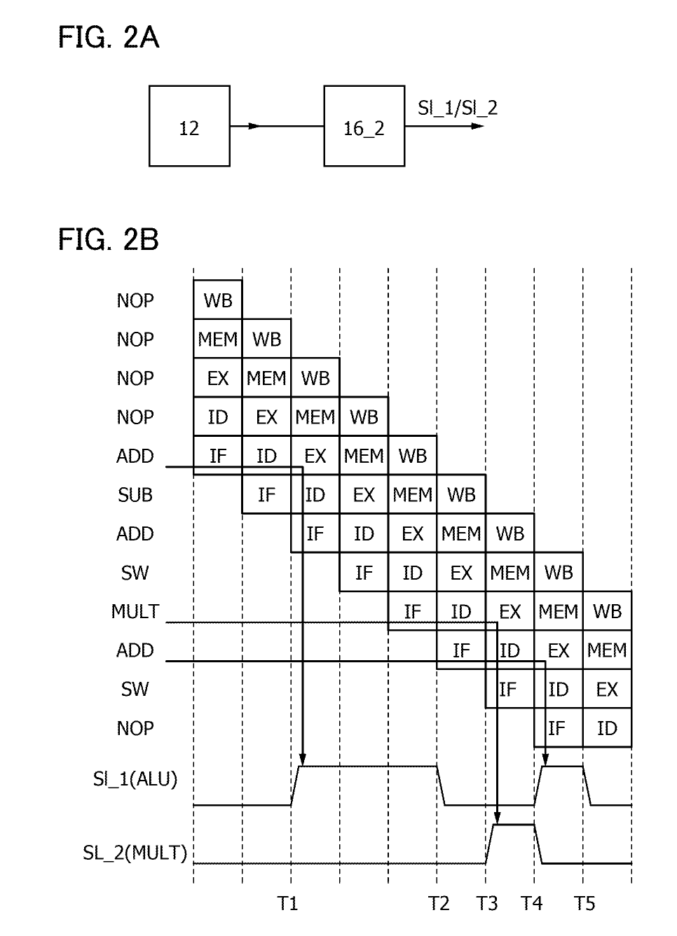

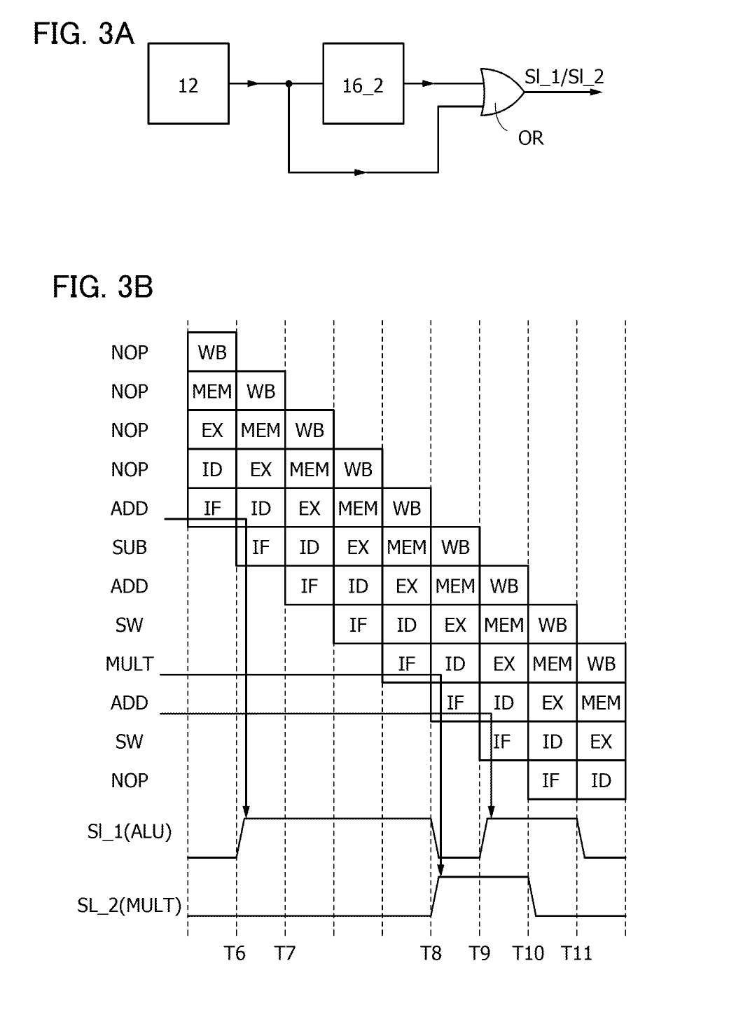

Next, an example of a specific operation of the semiconductor device in FIG. 1 will be described with reference to FIGS. 2A and 2B and FIGS. 3A and 3B.

In FIGS. 2A and 2B, the control signals S1_1 and S1_2 are output from the pipeline register 16_2. The control signals S1_1 and S1_2 output from the pipeline register 16_2 are generated in the instruction decode stage and the levels of the control signals S1_1 and S1_2 are switched in synchronization with the transfer of data to the next execution stage. In FIG. 2A, the control signals S1_1 and S1_2 output from the pipeline register 16_2 are illustrated.

In FIG. 2B, an example of an operation with the control signals S1_1 and S1_2 at the time of executing a pipeline processing in the semiconductor device 100 in FIG. 1 is illustrated. In the description of the operation, an ALU is used as the arithmetic unit 17_1 in FIG. 1, which executes an instruction for addition, subtraction, or the like. Furthermore, in the description of the operation, a MULT is used as the arithmetic unit 17_2 in FIG. 1, which executes an instruction for multiplication or the like.

In FIG. 2B, examples of an instruction to be executed in the semiconductor device are illustrated to describe an operation example. For example, a NOP instruction (NOP in the drawing) denotes an instruction for no action. An ADD instruction (ADD in the drawing) denotes an instruction for addition. A SUB instruction (SUB in the drawing) denotes an instruction for subtraction. An SW instruction (SW in the drawing) denotes an instruction for writing data to a data memory. A MULT instruction (MULT in the drawing) denotes an instruction for multiplication. When one of the ADD instruction, the SUB instruction, and the MULT instruction is input, the value of operand in the instruction or the value read from the register file 13 is input to the arithmetic unit to perform an arithmetic operation.

FIG. 2B illustrates an example of performing fetch (IF in the drawing), instruction decode (ID in the drawing), execution (EX in the drawing), memory access (MEM in the drawing), and write back (WB in the drawing) to describe the processing of data in response to the instruction to be executed in the semiconductor device.

In the operation illustrated in FIG. 2B, the processing of the NOP instruction and the processing of the SW instruction need neither the arithmetic unit 17_1 nor the arithmetic unit 17_2. In the operation illustrated in FIG. 2B, the processing of the ADD instruction and the processing of the SUB instruction need the arithmetic unit 17_1 at the time of executing the instruction. In the operation illustrated in FIG. 2B, the processing of the MULT instruction needs the arithmetic unit 17_2 at the time of executing the instruction. An address is calculated with the use of the ALU depending on the addressing of the SW instruction. In this embodiment, a description is given on the assumption that the addressing of the SW instruction does not use the ALU for the sake of simplicity.

In the operation illustrated in FIG. 2B, in a period from a time T1 to a time T2 during which the ADD instruction and the SUB instruction are executed and a period from a time T4 to a time T5 during which the ADD instruction is executed, the control signal S1_1 is set at the H level to turn on the transistor 18_1. By turning on the transistor 18_1, the power supply voltage is supplied to the arithmetic unit 17_1; thus, the instruction can be executed in the period from the time T1 to the time T2 and the period from the time T4 to the time T5. Furthermore, in periods other than the period from the time T1 to the time T2 and the period from the time T4 to the time T5, the instruction is not executed and the transistor 18_1 is made off so that the supply of the power supply voltage to the arithmetic unit 17_1 is stopped; in this manner, power gating can be performed.

In the operation illustrated in FIG. 2B, in a period from a time T3 to the time T4 during which the MULT instruction is executed, the control signal S1_2 is set at the H level to turn on the transistor 18_2. By turning on the transistor 18_2, the power supply voltage is supplied to the arithmetic unit 17_2; thus, the instruction can be executed in the period from the time T3 to the time T4. Furthermore, in periods other than the period from the time T3 to the time T4, the instruction is not executed and the transistor 18_2 is made off so that the supply of the power supply voltage to the arithmetic unit 17_2 is stopped; in this manner, power gating can be performed.

In the description of the operation illustrated in FIG. 2B, the control signals S1_1 and S1_2 are controlled so that the power supply voltage is supplied just before the instruction for the arithmetic operation is executed; however, another structure may be employed. For example, at the time of decoding the instruction, depending on whether to execute the arithmetic operation with the use of the arithmetic unit, the control signals S1_1 and S1_2 may be controlled so that the power supply voltage is supplied.

In FIGS. 3A and 3B, the control signals S1_1 and S1_2 are output from the decoder 12 and the pipeline register 16_2. The levels of the control signals S1_1 and S1_2 output from the decoder 12 and the pipeline register 16_2 are switched in synchronization with the output from the decoder 12 in the instruction decode stage. In FIG. 3A, the control signals S1_1 and S1_2 are illustrated, which are obtained in such a manner that a signal output from the decoder 12 and a signal output from the pipeline register 16_2 are input to an OR circuit OR. The control signals S1_1 and S1_2 are output in the configuration of FIG. 3A, whereby the supply of the power supply voltage to the arithmetic unit in the execution stage can be restarted when an instruction for the arithmetic operation is decoded in the instruction decode stage. In the case where noise is generated in decoding the instruction, a noise removing circuit is preferably provided inside the decoder 12.

In FIG. 3B, an example of an operation with the control signals S1_1 and S1_2 at the time of executing a pipeline processing in the semiconductor device 100 in FIG. 1 is illustrated. Note that the functions of the arithmetic portions and the instructions to be executed in the description of the operation are similar to those illustrated in FIG. 2B.

In the operation illustrated in FIG. 3B, in a period from a time T6 to a time T8 during which the ADD instruction and the SUB instruction are decoded and executed and a period from a time T9 to a time T11 during which the ADD instruction is decoded and executed, the control signal S1_1 is set at the H level to turn on the transistor 18_1. By turning on the transistor 18_1, the power supply voltage is supplied to the arithmetic unit 17_1 in a period from the time T6 to a time T7 and a period from the time T9 to a time T10 before the instruction is executed; thus, the instruction can be executed in a period from the time T7 to the time T8 and a period from the time T10 to the time T11. Furthermore, in periods other than the period from the time T6 to the time T8 and the period from the time T9 to the time T11, the transistor 18_1 is made off so that the supply of the power supply voltage to the arithmetic unit 17_1 is stopped; in this manner, power gating can be performed.

In the operation illustrated in FIG. 3B, in a period from the time T8 to the time T10 during which the MULT instruction is decoded and executed, the control signal S1_2 is set at the H level to turn on the transistor 18_2. By turning on the transistor 18_2, the power supply voltage is supplied to the arithmetic unit 17_2 in a period from the time T8 to the time T9 before the instruction is executed; thus, the instruction can be executed in the period from the time T9 to the time T10. Furthermore, in periods other than the period from the time T8 to the time T10, the transistor 18_2 is made off so that the supply of the power supply voltage to the arithmetic unit 17_2 is stopped; in this manner, power gating can be performed.

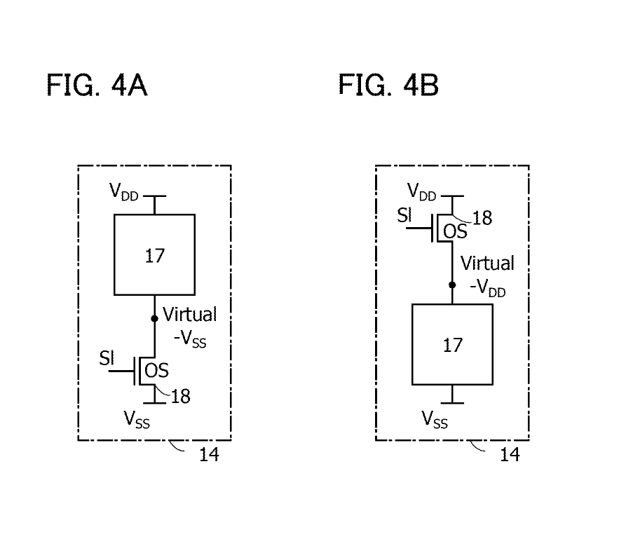

Note that in FIG. 1, the transistor for power gating is connected to the wiring through which the potential V_{SS} is supplied of the wirings through which the power supply voltage is supplied. Such a configuration of an arithmetic portion 14 is illustrated in FIG. 4A.

The arithmetic portion 14 in FIG. 4A includes an arithmetic unit 17 and a transistor 18. Power gating for the arithmetic unit 17 is performed in such a manner that the on/off state of the transistor 18 is controlled by a control signal S1 By turning on the transistor, the potential of a node represented by Virtual-V_{SS} in FIG. 4A becomes the potential V_{SS}; thus, the power supply voltage is supplied to the arithmetic unit 17. On the other hand, by turning off the transistor, the potential of the node represented by Virtual-V_{SS} in FIG. 4A becomes the potential V_{DD} due to leakage current or through current flowing through the arithmetic unit 17; thus, the supply of the power supply voltage to the arithmetic unit 17 is stopped.

The configuration of the arithmetic portion 14 is not limited to that illustrated in FIG. 4A. For example, the transistor 18 may be connected to the wiring through which the potential V_{DD} is supplied of the wirings through which the power supply voltage is supplied. Such a configuration of the arithmetic portion 14 is illustrated in FIG. 4B.

The arithmetic portion 14 in FIG. 4B includes the arithmetic unit 17 and the transistor 18. The on/off state of the transistor 18 is controlled by the control signal S1. By turning on the transistor, the potential of a node represented by Virtual-V_{DD} in FIG. 4B becomes the potential V_{DD}; thus, the power supply voltage is supplied to the arithmetic unit 17. On the other hand, by turning off the transistor, the potential of the node represented by Virtual-V_{DD} in FIG. 4B becomes the potential V_{SS} due to leakage current or through current flowing through the arithmetic unit 17; thus, the supply of the power supply voltage to the arithmetic unit 17 is stopped.

The transistor 18 illustrated in FIGS. 4A and 4B is preferably an OS transistor whose off-state current is low. As an oxide semiconductor that can be used for the OS transistor, an oxide semiconductor containing In, Ga, and Zn is preferably used. In the circuit diagrams, “OS” is written beside the transistor 18 in order to clearly demonstrate that the transistor 18 is an OS transistor.

In the circuit configurations illustrated in FIGS. 4A and 4B, a back gate may be added to the transistor 18. By applying a negative potential to the back gate to positively shift the threshold voltage of the transistor 18, the off-state current of the transistor 18 can be kept low. By applying a positive potential to the back gate to negatively shift the threshold voltage of the transistor 18, the on-state current of the transistor 18 can be increased.

Note that there is no particular limitation on the structure of the transistor 18; for example, a top-gate structure or a bottom-gate structure can be employed.

Next, a layout example of the transistor for performing power gating for the arithmetic unit will be described. The arithmetic unit is formed using a basic combination circuit such as an inverter circuit, a NAND circuit, or a NOR circuit. The transistor for power gating may be provided for each arithmetic unit; alternatively, the transistor for power gating may be provided for each combination circuit.

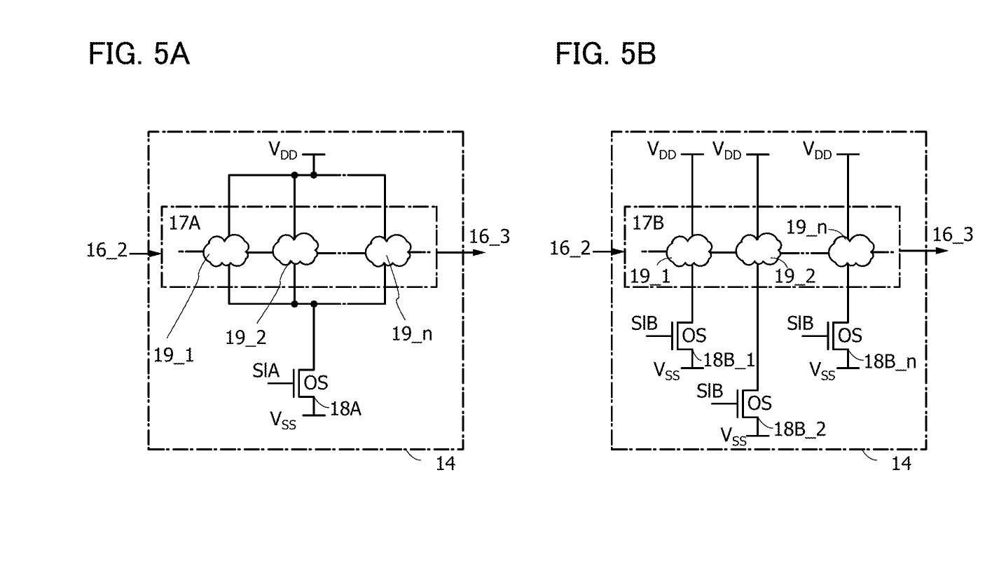

The arithmetic portion 14 in FIG. 5A has a circuit configuration in which a transistor 18A is provided for an arithmetic unit 17A. The arithmetic unit 17A has combination circuits 19_1 to 19_{—}n (n is a natural number). To the arithmetic unit 17A, for example, data to be used for an arithmetic operation is input from the pipeline register 16_2. Data after the arithmetic operation is output to the pipeline register 16_3 through the combination circuits 19_1 to 19_{—}n.

The on/off state of the transistor 18A in FIG. 5A is controlled by a control signal S1A. The supply of the power supply voltage to the combination circuits 19_1 to 19_{—}n depends on the on/off state of the transistor 18A.

An OS transistor is used as the transistor 18A; thus, an effect of low power consumption due to low off-state current can be achieved, and an increase in circuit area can be prevented even when transistors for power gating are additionally provided so that area overhead can be reduced.

Note that an OS transistor is an accumulation-type transistor in which electrons are majority carriers. An electric field extended from conductive layers serving as source and drain electrodes in contact with an oxide semiconductor layer to a channel formation region can be blocked within a short distance. Thus, short-channel effects are unlikely to occur in the OS transistor, so that an LDD region is not required. In other words, a shorter channel length does not lead to lower mobility in the OS transistor.

In contrast, in a Si transistor with a short channel, short-channel effects arise. To prevent short-channel effects, the Si transistor needs to be provided with an LDD region. The mobility of the Si transistor is lowered by the influence of the LDD region. The configuration of the arithmetic portion including the OS transistor can solve the issue of mobility reduction of a fine Si transistor due to mobility dependence on gate length.

When there is a large difference in mobility between a Si transistor and an OS transistor that have a gate length with which short-channel effects do not occur, the gate width of the OS transistor needs to be set larger than that of the Si transistor. In contrast, with a smaller gate length due to miniaturization with which short-channel effects occur, the difference in mobility between a Si transistor and an OS transistor is reduced. Accordingly, the arithmetic portion including the OS transistor enables a reduction in difference in gate width between the OS transistor and the Si transistor.

In addition, the S value of the OS transistor is smaller than that of the Si transistor. For this reason, the switching operation at the time of resuming operation in power gating can be performed at high speed. Furthermore, the subthreshold leakage current of the OS transistor having small S value can be lower than that of the Si transistor. In the case of the Si transistor, the threshold voltage is shifted so that the Si transistor functions as an enhancement-type transistor and thus the subthreshold leakage current is made small. In contrast, in the case of the OS transistor, the subthreshold leakage current can be significantly small without controlling the threshold voltage of the OS transistor.

A different configuration of the arithmetic portion 14 from the configuration illustrated in FIG. 5A will be described. Like the arithmetic unit 17A illustrated in FIG. 5A, an arithmetic unit 17B is included in the arithmetic portion 14 illustrated in FIG. 5B. Transistors 18B_1 to 18B_n are connected to the combination circuits 19_1 to 19_{—}n in the arithmetic unit 17B, respectively.

The on/off state of each of the transistors 18B_1 to 18B_n in FIG. 5B is controlled by a control signal S1B. The combination circuits 19_1 to 19_{—}n are controlled to be supplied or not to be supplied with the power supply voltage depending on the respective on/off states of the transistors 18B_1 to 18B_n.

In the configuration illustrated in FIG. 5B, a circuit in which the combination circuit 19_1 and the transistor 18B_1 are used in combination can be regarded as the minimum unit of a combination circuit. For this reason, logic synthesis based on functions of an arithmetic unit can be performed using, as a standard cell, a combination circuit as a minimum unit in which a transistor is incorporated. In this case, design simplification can be achieved compared with the case where, after logic synthesis, a circuit configuration of transistors for power gating is further taken into consideration.

OS transistors are used as the transistors 18B_1 to 18B_n; thus, an increase in circuit area can be prevented even when transistors for power gating are additionally provided, and a reduction in power consumption can be achieved.

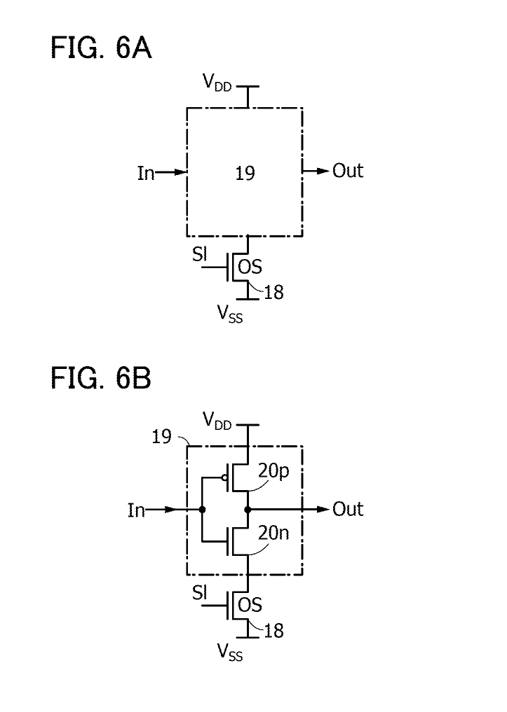

Examples of the combination circuits 19_1 to 19_{—}n illustrated in FIGS. 5A and 5B will be described with reference to FIGS. 6A and 6B.

In FIG. 6A, a combination circuit 19 and the transistor 18 for power gating are illustrated. As the combination circuit 19, a circuit with a standard cell level such as an inverter circuit, a NAND circuit, or a NOR circuit is preferably used depending on functions of the arithmetic unit as described above. The combination circuit 19 outputs a signal input from an input terminal In to an output terminal Out. The number of input signals and that of output signals may each be two or more.

FIG. 6B illustrates an example of a circuit configuration in which an inverter circuit is used as the combination circuit 19. The combination circuit 19 illustrated in FIG. 6B includes, for example, a p-channel transistor 20p and an n-channel transistor 20n which form an inverter circuit. The inverter circuit inverts the logic of a signal input from the input terminal In and outputs the inverted signal to the output terminal Out. Note that Si transistors are preferably used as the transistor 20p and the transistor 20n. Between wirings through which the power supply voltage is supplied, the transistor 18 is provided in series with the transistor 20p and the transistor 20n. An OS transistor is preferably used as the transistor 18 as described above.

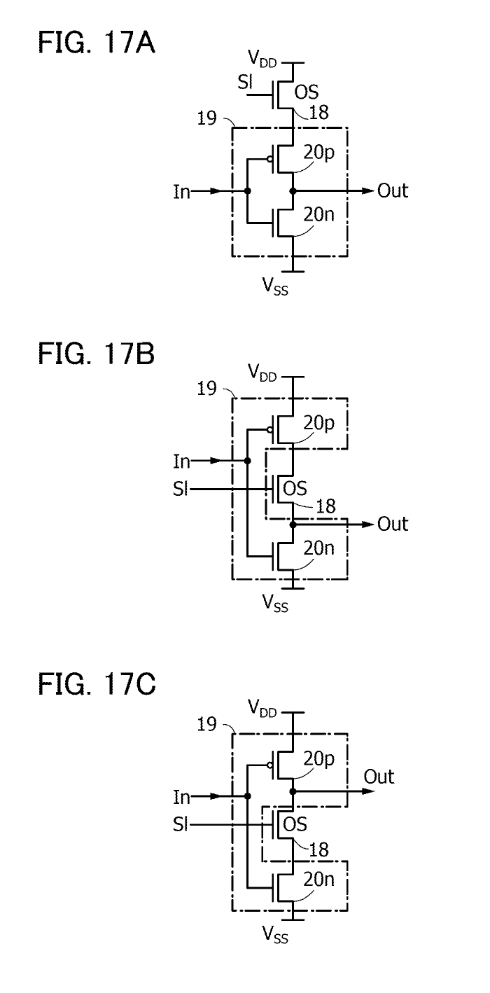

Note that a configuration in which the transistor 18 is connected to the wiring through which the potential V_{SS} is supplied is illustrated in FIG. 6B; however, another configuration may be employed. For example, configurations illustrated in FIGS. 17A to 17C may alternatively be employed as long as the transistor 18 is provided between the wirings through which the power supply voltage is supplied.

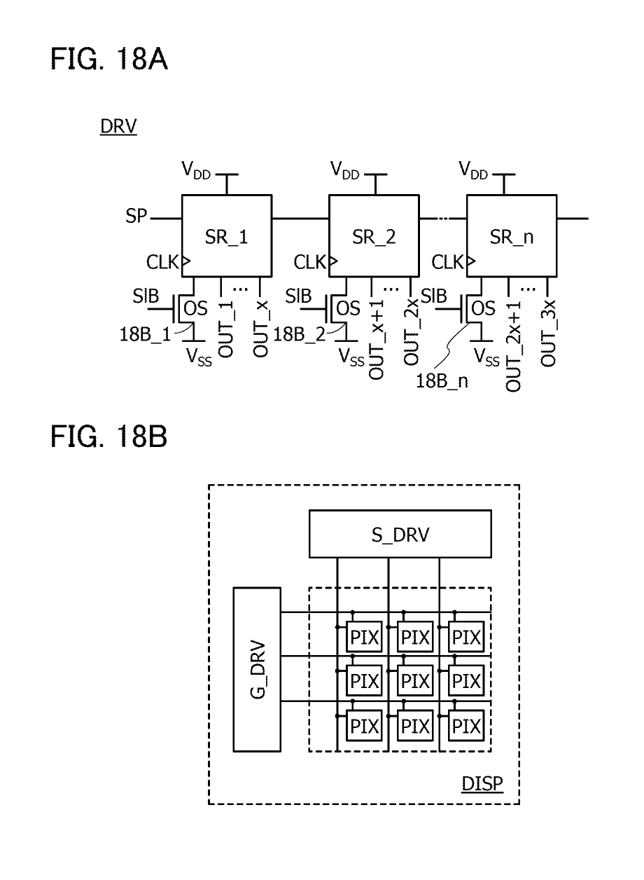

FIGS. 5A and 5B each illustrate a configuration in which a combination circuit and an OS transistor are used; however, another configuration may be employed. For example, a sequential circuit may be used instead of the combination circuit. As an example of the sequential circuit, a flip-flop can be given. FIG. 18A illustrates a configuration example of a driver circuit DRV including the OS transistors 18B_1 to 18B_n performing power gating for shift registers SR_1 to SR_n including flip-flops. In FIG. 18A, CLK denotes a clock signal, SP denotes a start pulse, and OUT_1 to OUT_x (x is a natural number of 2 or more), OUT_x+1 to OUT_2x, and OUT_2x+1 to OUT_3x denote output pulse signals.

The driver circuit DRV illustrated in FIG. 18A can be used as a source driver S_DRV and/or a gate driver G_DRV in a display device DISP illustrated in FIG. 18B. As a display element that can be used for a pixel PIX, for example, at least one of the following is included: a liquid crystal element, an electroluminescence (EL) element (e.g., an EL element including organic and inorganic materials, an organic EL element, or an inorganic EL element), an LED (e.g., a white LED, a red LED, a green LED, or a blue LED), a transistor (a transistor that emits light depending on current), an electron emitter, electronic ink, an electrophoretic element, a grating light valve (GLV), a plasma display panel (PDP), a display element using micro electro mechanical system (MEMS), a digital micromirror device (DMD), a digital micro shutter (DMS), MIRASOL (registered trademark), an interferometric modulator (IMOD) element, a MEMS shutter display element, an optical-interference-type MEMS display element, an electrowetting element, a piezoelectric ceramic display, and a display element including a carbon nanotube. Other than the above, display media whose contrast, luminance, reflectivity, transmittance, or the like is changed by electrical or magnetic effect may be included.

Next, such a stacked structure of Si transistors and an OS transistor as is illustrated in FIG. 6B will be described with reference to FIGS. 7A, 7B-1, and 7B-2. Note that FIGS. 7A, 7B-1, and 7B-2 are just schematic diagrams; the size of an OS transistor is preferably adjusted so that logic can function appropriately.

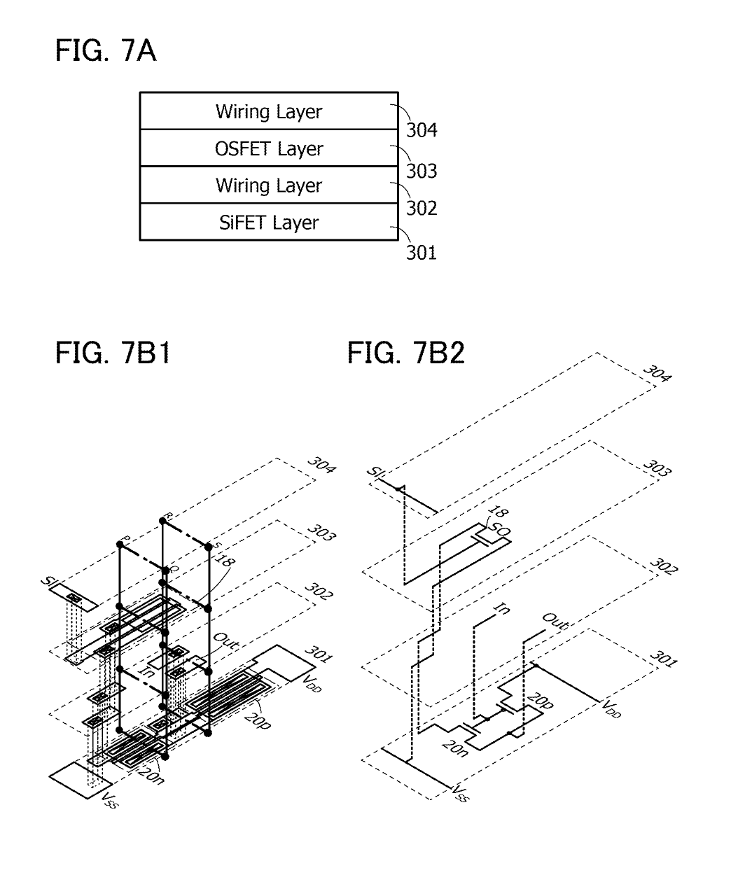

FIG. 7A is a schematic diagram of a stacked structure of Si transistors and an OS transistor. In FIG. 7A, a first layer 301 is a layer provided with Si transistors (denoted by SiFET Layer in the drawing). A second layer 302 is a layer provided with a wiring layer (denoted by Wiring Layer in the drawing). A third layer 303 is a layer provided with an OS transistor (denoted by OSFET Layer in the drawing). A fourth layer 304 is a layer provided with a wiring layer (denoted by Wiring Layer in the drawing).

In FIG. 7B-1, an example of a layout in the circuit configuration of FIG. 6B is shown in the first to fourth layers 301 to 304. In FIG. 7B-2, the circuit configuration is shown in the first to fourth layers 301 to 304 having the stacked structure of FIG. 7A.

In the layout illustrated in FIG. 7B-1, the transistor 20p and the transistor 20n which are Si transistors and the wirings through which the potential V_{DD} and the potential V_{SS} are supplied are in the first layer 301. The transistor 20p and the transistor 20n each include a conductive layer serving as a gate electrode, an insulating layer serving as a gate insulating layer, conductive layers serving as a source electrode and a drain electrode, and a semiconductor layer in which silicon is used for a channel formation region. The wirings through which the potential V_{DD} and the potential V_{SS} are supplied are provided in the same layer as the conductive layers serving as the source electrode and the drain electrode. The wiring through which the potential V_{DD} is supplied is electrically connected to the drain electrode of the transistor 20p.

A wiring functioning as an input terminal In, a wiring functioning as an output terminal Out, and wirings connecting the upper layer and the lower layer are in the second layer 302. The wiring functioning as the input terminal In is electrically connected to the gate electrodes of the transistor 20p and the transistor 20n through a conductive layer provided in openings (also referred to as contact holes). The wiring functioning as the output terminal Out is electrically connected to the source electrode of the transistor 20p and the drain electrode of the transistor 20n through a conductive layer provided in openings (also referred to as contact holes). The wirings connecting the upper layer and the lower layer are electrically connected to the source electrode of the transistor 20n and the wiring through which the potential V_{SS} is supplied through conductive layers provided in openings.

The transistor 18 that is an OS transistor is in the third layer 303. The transistor 18 includes a conductive layer serving as a gate electrode, an insulating layer serving as a gate insulating layer, conductive layers serving as a source electrode and a drain electrode, and a semiconductor layer in which an oxide semiconductor is used for a channel formation region. One of the source electrode and the drain electrode of the transistor 18 is electrically connected to one of the wirings connecting the upper layer and the lower layer in the second layer 302 through a conductive layer provided in an opening. The other of the source electrode and the drain electrode of the transistor 18 is electrically connected to the other of the wirings connecting the upper layer and the lower layer in the second layer 302 through a conductive layer provided in an opening.

The wiring through which the control signal S1 is supplied is in the fourth layer 304. The wiring through which the control signal S1 is supplied is electrically connected to the conductive layer serving as the gate electrode of the transistor 18 in the third layer 303 through a conductive layer provided in an opening.

In the circuit configuration having the stacked structure illustrated in FIG. 7B-2, the transistor 20p and the transistor 20n which are Si transistors and the wirings through which the potential V_{DD} and the potential V_{SS} are supplied are in the first layer 301. The input terminal In, the output terminal Out, and the wirings connecting the upper layer and the lower layer are in the second layer 302. The transistor 18 that is an OS transistor is in the third layer 303. The wiring through which the control signal S1 is supplied is in the fourth layer 304. The connection relations of the wirings and the transistors in the first to fourth layers 301 to 304 are the same as those illustrated in FIG. 6B.

With the stacked structure of Si transistors and an OS transistor illustrated in FIGS. 7A, 7B-1, and 7B-2, a layout in which an increase in area due to the additionally provided OS transistor is prevented can be achieved.

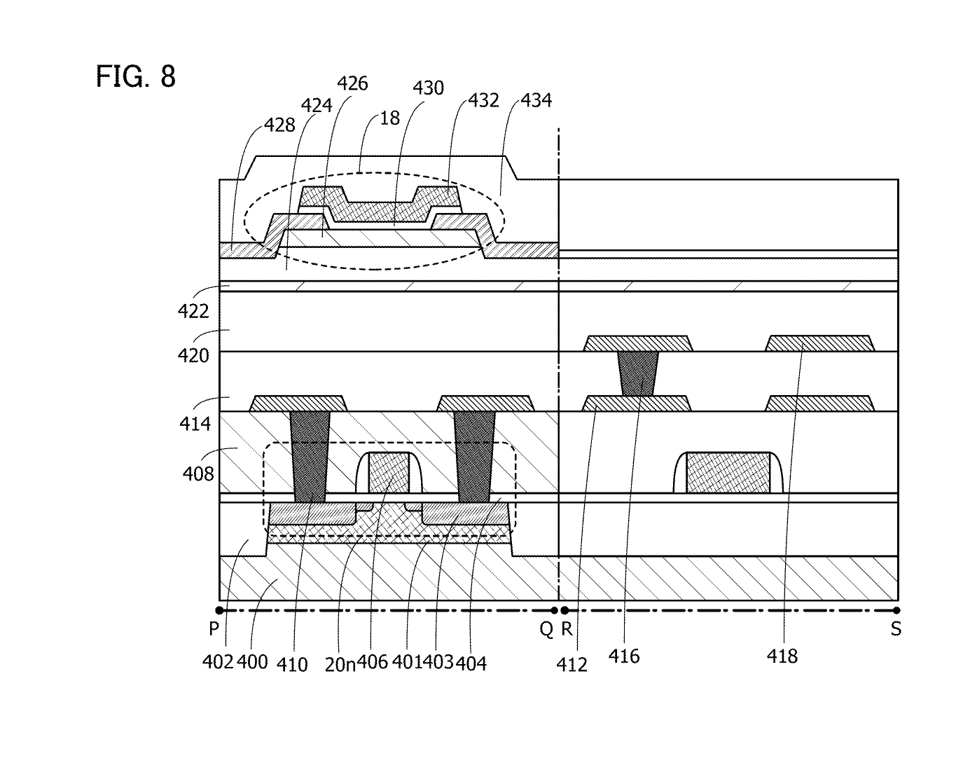

FIG. 8 is a cross-sectional view taken along dashed-dotted lines P-Q and R-S in FIG. 7B-1.

In the cross-sectional view of FIG. 8, the transistor 18 that is an OS transistor is provided over the transistor 20n that is a Si transistor. In the case of FIG. 8, the source electrode and the drain electrode of the transistor 20n overlap with the source electrode and the drain electrode of the transistor 18. Consequently, an increase in area due to the transistor 18 can be prevented, and thus the semiconductor device can be reduced in size.

A semiconductor substrate 400, a p-type impurity region 401, an element isolation insulating layer 402, n-type impurity regions 403, a gate insulating layer 404, a gate electrode 406, an interlayer insulating layer 408, conductive layers 410, wiring layers 412, an interlayer insulating layer 414, a conductive layer 416, wiring layers 418, an interlayer insulating layer 420, an interlayer insulating layer 422, an interlayer insulating layer 424, a semiconductor layer 426, wiring layers 428, a gate insulating layer 430, a gate electrode 432, and an interlayer insulating layer 434 are illustrated in FIG. 8.

The semiconductor substrate 400 can be, for example, an n-type or p-type silicon substrate, a germanium substrate, a silicon germanium substrate, or a compound semiconductor substrate (e.g., a GaAs substrate, an InP substrate, a GaN substrate, a SiC substrate, a GaP substrate, a GaInAsP substrate, or a ZnSe substrate).

The transistor 20n is electrically isolated from another transistor by the element isolation insulating layer 402. The element isolation insulating layer 402 can be formed by a local oxidation of silicon (LOCOS) method, a trench isolation method (a shallow trench isolation (STI) method), or the like.

The gate insulating layer 404 is formed in such a manner that a surface of the semiconductor substrate 400 is oxidized by heat treatment, so that a silicon oxide film is formed, and then the silicon oxide film is selectively etched. Alternatively, the gate insulating layer 404 is formed in such a manner that silicon oxide, silicon oxynitride, a metal oxide such as hafnium oxide, which is a high dielectric constant material (also referred to as a high-k material), or the like is formed by a CVD method, a sputtering method, or the like and then is selectively etched.

The gate electrode 406, the conductive layers 410, the wiring layers 412, the conductive layer 416, the wiring layers 418, the wiring layers 428, and the gate electrode 432 are preferably formed using a metal material such as aluminum, copper, titanium, tantalum, or tungsten. Alternatively, polycrystalline silicon to which an impurity such as phosphorus is added can be used. As the formation method, a variety of film formation methods such as an evaporation method, a PE-CVD method, a sputtering method, and a spin coating method can be used.

The gate insulating layer 404, the interlayer insulating layer 408, the interlayer insulating layer 414, the interlayer insulating layer 420, the interlayer insulating layer 424, and the interlayer insulating layer 434 are each preferably a single layer or a multilayer formed using an inorganic insulating layer or an organic insulating layer. The inorganic insulating layer is preferably a single layer or a multilayer formed using a silicon nitride film, a silicon oxynitride film, a silicon nitride oxide film, or the like. The organic insulating layer is preferably a single layer or a multilayer formed using polyimide, acrylic, or the like. There is no particular limitation on the method for forming each of the insulating layers; for example, a sputtering method, an MBE method, a PE-CVD method, a pulse laser deposition method, an ALD method, or the like can be employed as appropriate.

The semiconductor layer 426 can be a single layer or a stack formed using an oxide semiconductor. The oxide semiconductor is an oxide film containing at least indium, gallium, and zinc, and can be formed using an In—Ga—Zn-based oxide (also expressed as IGZO). Note that the In—Ga—Zn-based oxide means an oxide containing In, Ga, and Zn, and may contain a metal element other than In, Ga, and Zn. For example, it is possible to use an In—Sn—Ga—Zn-based oxide, an In—Hf—Ga—Zn-based oxide, or an In—Al—Ga—Zn-based oxide. The oxide semiconductor can be formed by a sputtering method, an atomic layer deposition (ALD) method, an evaporation method, a coating method, or the like.

The gate insulating layer 430 is preferably a single layer or a multilayer formed using an inorganic insulating layer. The gate insulating layer 430 preferably has an effect of supplying oxygen to the semiconductor layer 426.

The interlayer insulating layer 422 preferably has an effect of blocking diffusion of oxygen, hydrogen, and water. As the interlayer insulating layer 422 has higher density and becomes denser or has a fewer dangling bonds and becomes more chemically stable, the interlayer insulating layer 422 has a higher blocking effect. The interlayer insulating layer 422 having an effect of blocking diffusion of oxygen, hydrogen, and water can be formed using, for example, aluminum oxide, aluminum oxynitride, gallium oxide, gallium oxynitride, yttrium oxide, yttrium oxynitride, hafnium oxide, or hafnium oxynitride. The interlayer insulating layer 422 having an effect of blocking diffusion of hydrogen and water can be formed using silicon nitride or silicon nitride oxide, for example.

As described above, in the semiconductor device 100 that executes the pipeline processing described in this embodiment, the arithmetic units 17_1 and 17_2 are provided for the execution stage, to which, respectively, the transistors 18_1 and 18_2 for performing power gating are connected. Here, only the arithmetic unit that performs an arithmetic operation is supplied with the power supply voltage. Thus, fine-grained power gating can be performed, so that the power consumption of the semiconductor device can be reduced. In each of the transistors 18_1 and 18_2, a channel formation region includes an oxide semiconductor; thus, a reduction in leakage current between power supply lines can be achieved. Furthermore, these transistors and transistors in the arithmetic units can be provided in different layers, and thus an increase in area overhead due to the additionally provided transistors can be prevented.

The structure described above in this embodiment can be used in appropriate combination with any of the structures described in the other embodiments.

### Embodiment 2

In this embodiment, an example of a circuit configuration of the combination circuit in the arithmetic unit described in Embodiment 1, which is different from the circuit configuration of FIGS. 6A and 6B, will be described.

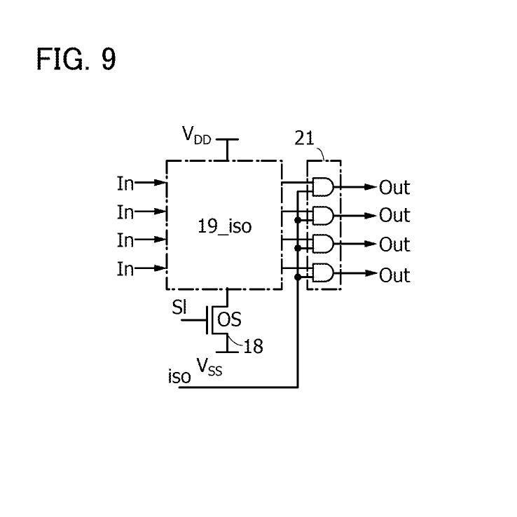

FIG. 9 illustrates, as a modification example of the combination circuit in FIG. 6A, a configuration in which the logic of a signal from an output terminal is fixed. In FIG. 9, an AND circuit 21 is provided between a combination circuit 19_{—}iso and output terminals Out. Signals output from the combination circuit 19_{—}iso and a control signal iso are input to the AND circuit 21.

When power gating for stopping supply of power supply voltage to an arithmetic portion including the combination circuit 19_{—}iso is performed, a signal output from the combination circuit 19_{—}iso is brought into an indefinite state and the logic of the output terminals Out is also brought into an indefinite state in some cases. For example, when an output signal in an indefinite state is input to a circuit block in the next stage to which the power supply voltage is supplied, unintentional current flows in some cases. For that reason, it is preferred that an output signal in an indefinite state from a circuit block including a combination circuit for which power gating has been performed be not input to a circuit block in the next stage. In order that an output signal in an indefinite state is not input, for example, the AND circuit 21 is provided and thus the control signal S1 is controlled; in this manner, the logic of the output terminal Out can be fixed. For example, in periods before and after the transistor 18 is turned off by controlling the control signal S1, the logic of the output terminal Out is fixed by controlling the control signal iso. With such a configuration, the logic of the output terminal Out can be fixed regardless of a signal output from the combination circuit 19_{—}iso.

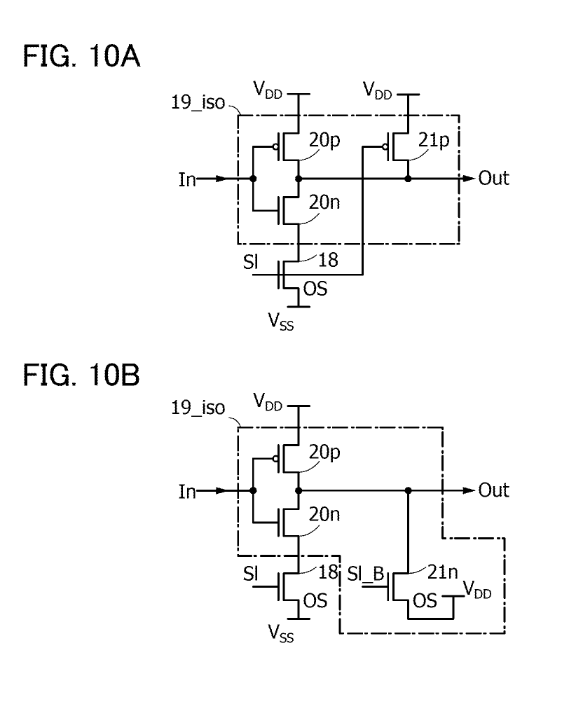

A configuration in which the AND circuit 21 is provided and the control signal iso is input is not necessarily employed to fix the logic of the output terminal Out. Another configuration will be described with reference to FIGS. 10A and 10B. In FIGS. 10A and 10B, the combination circuit 19_{—}iso has a configuration in which a transistor for fixing the logic of the output terminal Out is provided in addition to an inverter circuit including the transistor 20p and the transistor 20n.

As illustrated in FIG. 10A, a transistor 21p is provided between the wiring through which the potential V_{DD} is supplied and the output terminal Out and is controlled by the control signal S1. The transistor 21p needs to have a different conductivity type from the transistor 18 so that the transistor 21p and the transistor 18 are alternately turned on; in FIG. 10A, the transistor 21p is a p-channel transistor. With such a configuration, the potential of the output terminal Out can be made to be the potential V_{DD} in power gating, and thus the logic of the output terminal Out can be prevented from being in an indefinite state.

As illustrated in FIG. 10B, a transistor 21n is provided between the wiring through which the potential V_{DD} is supplied and the output terminal Out and is controlled by a control signal S1_B. The control signal S1_B is a signal obtained by inverting the control signal S1. The transistor 21n has the same conductivity type as the transistor 18, and is an n-channel transistor here. The transistor 21n and the transistor 18 can be alternately turned on. Furthermore, both the transistor 18 and the transistor 21n are OS transistors, and thus area overhead can be reduced. With such a configuration, the potential of the output terminal Out can be made to be the potential V_{DD} in power gating, and thus the logic of the output terminal Out can be prevented from being in an indefinite state.

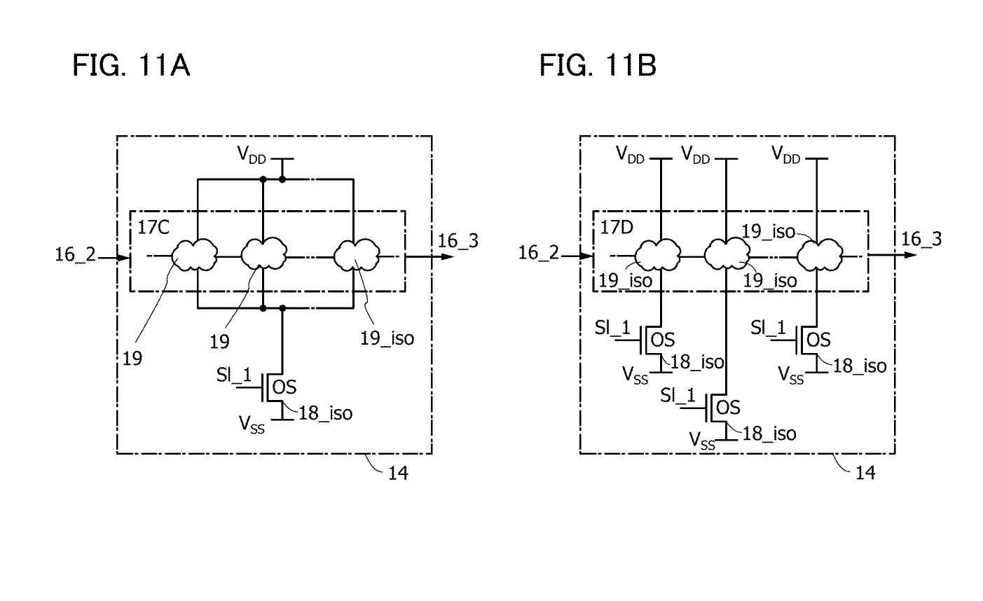

The combination circuit 19_{—}iso in FIG. 9 and FIGS. 10A and 10B with which the logic of the output terminal Out can be fixed may be provided in part of an arithmetic unit. For example, as illustrated in FIG. 11A, a configuration in which the combination circuit 19_{—}iso is provided in the last stage of combination circuits included in an arithmetic unit 17C and the combination circuit 19 illustrated in FIG. 6A is provided in the other stages may be employed.

The combination circuit 19_{—}iso with which the logic of the output terminal Out can be fixed in FIG. 9 and FIGS. 10A and 10B may be provided as all the combination circuits in an arithmetic unit. For example, as illustrated in FIG. 11B, the combination circuit 19_{—}iso may be provided as all the combination circuits in an arithmetic unit 17D.

As illustrated in FIG. 11B, the transistor 18_{—}iso and the combination circuit 19_{—}iso can be provided in combination. A circuit configuration including the transistor 18_{—}iso and the combination circuit 19_{—}iso is a fine-grained circuit block; thus, it can be used as a standard cell. Consequently, logic synthesis based on functions of an arithmetic unit can be performed with the standard cell including the transistors for power gating. In this case, design simplification can be achieved compared with the case where, after logic synthesis, a circuit configuration of transistors for power gating is further taken into consideration.

The structure described above in this embodiment can be used in appropriate combination with any of the structures described in the other embodiments.

### Embodiment 3

In this embodiment, an example of a structure which is different from a cross-sectional structure of the transistor 18 illustrated in FIG. 8 will be described.

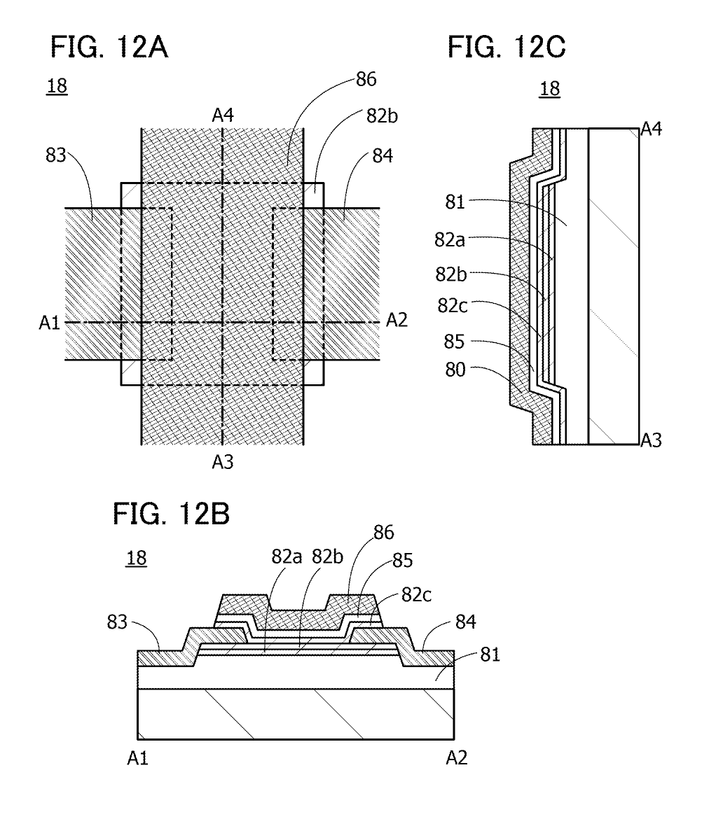

FIGS. 12A to 12C illustrate another specific example of the structure of the transistor 18. FIG. 12A is a top view of the transistor 18. Note that insulating layers are not illustrated in FIG. 12A in order to clarify the layout of the transistor 18. FIG. 12B is a cross-sectional view along dashed-dotted line A1-A2 in the top view of FIG. 12A. FIG. 12C is a cross-sectional view along dashed-dotted line A3-A4 in the top view of FIG. 12A.

As illustrated in FIGS. 12A to 12C, the transistor 18 includes oxide semiconductor layers 82a and 82b that are stacked in this order over an insulating layer 81; conductive layers 83 and 84 that are electrically connected to the oxide semiconductor layer 82b and function as a source electrode and a drain electrode; an oxide semiconductor layer 82c over the oxide semiconductor layer 82b and the conductive layers 83 and 84; an insulating layer 85 that functions as a gate insulating layer and is located over the oxide semiconductor layer 82c; and a conductive layer 86 that functions as a gate electrode, is over the insulating layer 85, and overlaps with the oxide semiconductor layers 82a to 82c.

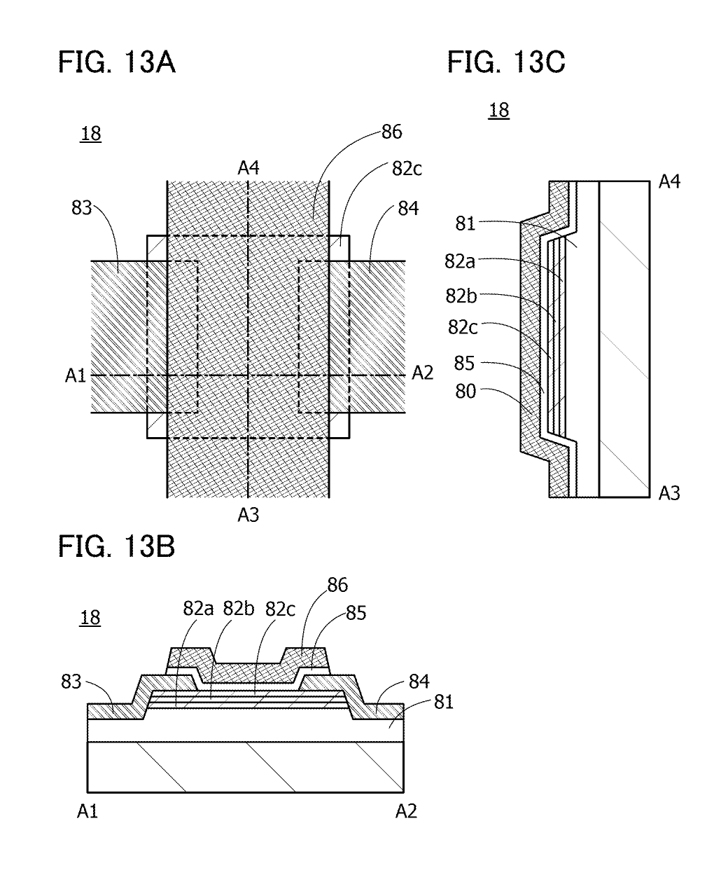

FIGS. 13A to 13C illustrate another specific example of the structure of the transistor 18. FIG. 13A is a top view of the transistor 18. Note that insulating layers are not illustrated in FIG. 13A in order to clarify the layout of the transistor 18. FIG. 13B is a cross-sectional view along dashed-dotted line A1-A2 in the top view of FIG. 13A. FIG. 13C is a cross-sectional view along dashed-dotted line A3-A4 in the top view of FIG. 13A.

As illustrated in FIGS. 13A to 13C, the transistor 18 includes the oxide semiconductor layers 82a to 82c that are stacked in this order over the insulating layer 81; the conductive layers 83 and 84 that are electrically connected to the oxide semiconductor layer 82c and function as a source electrode and a drain electrode; the insulating layer 85 that functions as a gate insulating layer and is located over the oxide semiconductor layer 82c, the conductive layer 83, and the conductive layer 84; and the conductive layer 86 that functions as a gate electrode, is over the insulating layer 85, and overlaps with the oxide semiconductor layers 82a to 82c.

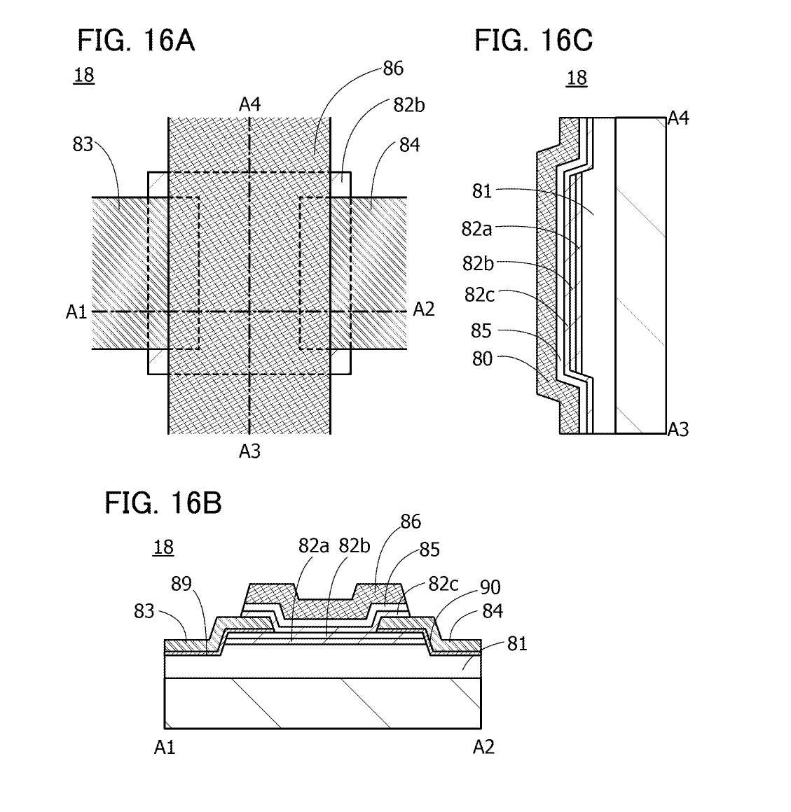

FIGS. 16A to 16C illustrate another specific example of the structure of the transistor 18. FIG. 16A is a top view of the transistor 18. Note that insulating layers are not illustrated in FIG. 16A in order to clarify the layout of the transistor 18. FIG. 16B is a cross-sectional view along dashed-dotted line A1-A2 in the top view of FIG. 16A. FIG. 16C is a cross-sectional view along dashed-dotted line A3-A4 in the top view of FIG. 16A.

As illustrated in FIGS. 16A to 16C, the transistor 18 includes the oxide semiconductor layers 82a to 82c that are stacked in this order over the insulating layer 81; the conductive layers 83 and 84 and layers 89 and 90 that are electrically connected to the oxide semiconductor layer 82c and function as a source electrode and a drain electrode; the insulating layer 85 that functions as a gate insulating layer and is located over the oxide semiconductor layer 82c, the conductive layer 83, and the conductive layer 84; and the conductive layer 86 that functions as a gate electrode, is over the insulating layer 85, and overlaps with the oxide semiconductor layers 82a to 82c.

The layers 89 and 90 are layers having a function of not forming a Schottky barrier with the oxide semiconductor layers 82a to 82c and the like. For example, these layers are layers of a transparent conductor, an oxide semiconductor, a nitride semiconductor, or an oxynitride semiconductor. More specifically, the layers 89 and 90 may be formed using a layer containing indium, tin, and oxygen, a layer containing indium and zinc, a layer containing indium, tungsten, and zinc, a layer containing tin and zinc, a layer containing zinc and gallium, a layer containing zinc and aluminum, a layer containing zinc and fluorine, a layer containing zinc and boron, a layer containing tin and antimony, a layer containing tin and fluorine, a layer containing titanium and niobium, or the like. Alternatively, any of these layers may contain hydrogen, carbon, nitrogen, silicon, germanium, or argon. With the structure including the layers 89 and 90, on-state characteristics of the transistor can be improved.

FIGS. 12A to 12C and FIGS. 13A to 13C each illustrate the structure example of the transistor 18 in which the oxide semiconductor layers 82a to 82c are stacked. However, the structure of the oxide semiconductor layer included in the transistor 18 is not limited to a stacked structure including a plurality of oxide semiconductor layers and may be a single-layer structure.

In the case where the transistor 18 includes the oxide semiconductor layers 82a to 82c stacked in this order, each of the oxide semiconductor layers 82a and 82c is an oxide film that contains at least one of metal elements contained in the oxide semiconductor layer 82b and in which the conduction band minimum is closer to the vacuum level than that in the oxide semiconductor layer 82b is by higher than or equal to 0.05 eV, 0.07 eV, 0.1 eV, or 0.15 eV and lower than or equal to 2 eV, 1 eV, 0.5 eV, or 0.4 eV. The oxide semiconductor layer 82b preferably contains at least indium because carrier mobility is increased.

In the case where the transistor 18 includes the semiconductor layers with the above structure, when an electric field is applied to the semiconductor layers by applying voltage to the gate electrode, a channel region is formed in the oxide semiconductor layer 82b, which has the lowest conduction band minimum among the semiconductor layers. That is, the oxide semiconductor layer 82c provided between the oxide semiconductor layer 82b and the insulating layer 85 makes it possible to form the channel region in the oxide semiconductor layer 82b, which is separated from the insulating layer 85.

Since the oxide semiconductor layer 82c contains at least one of the metal elements contained in the oxide semiconductor layer 82b, interface scattering is less likely to occur at the interface between the oxide semiconductor layer 82b and the oxide semiconductor layer 82c. Thus, the movement of carriers is less likely to be inhibited at the interface, which results in an increase in the field-effect mobility of the transistor 18.

In the case where gallium oxide is used for the oxide semiconductor layer 82c, indium in the oxide semiconductor layer 82b can be prevented from being diffused into the insulating layer 85; thus, the leakage current of the transistor 18 can be reduced.

When an interface level is formed at the interface between the oxide semiconductor layer 82b and the oxide semiconductor layer 82a, a channel region is formed also in the vicinity of the interface, which causes a change in the threshold voltage of the transistor 18. However, since the oxide semiconductor layer 82a contains at least one of the metal elements contained in the oxide semiconductor layer 82b, an interface level is less likely to be formed at the interface between the oxide semiconductor layer 82b and the oxide semiconductor layer 82a. Accordingly, the above structure allows reducing of variations in the electrical characteristics of the transistor 18, such as the threshold voltage.

Further, it is preferable that a plurality of oxide semiconductor layers be stacked so that an interface level due to an impurity existing between the oxide semiconductor layers, which inhibits carrier flow, is not formed at the interface between the oxide semiconductor layers. This is because when an impurity exists between the stacked oxide semiconductor layers, the continuity of the conduction band minimum between the oxide semiconductor layers is lost, and carriers are trapped or disappear by recombination in the vicinity of the interface. By reducing an impurity existing between the films, a continuous junction (here, in particular, a U-shape well structure whose conduction band minimum is changed continuously between the films) is formed more easily than the case of merely stacking a plurality of oxide semiconductor layers which contain at least one metal in common as a main component.

In order to form such a continuous junction, the films need to be stacked successively without being exposed to the air by using a multi-chamber deposition system (sputtering apparatus) provided with a load lock chamber. Each chamber of the sputtering apparatus is preferably evacuated to a high vacuum (to approximately 5×10⁻⁷ Pa to 1×10⁻⁴ Pa) by an adsorption vacuum pump such as a cryopump so that water and the like acting as impurities for the oxide semiconductor are removed as much as possible. Alternatively, a turbo molecular pump and a cold trap are preferably used in combination to prevent backflow of gas into the chamber through an evacuation system.

To obtain a highly purified intrinsic oxide semiconductor, not only high vacuum evacuation of the chambers but also high purification of a gas used in the sputtering is important. When an oxygen gas or an argon gas used as the above gas has a dew point of −40° C. or lower, preferably −80° C. or lower, further preferably −100° C. or lower and is highly purified, moisture and the like can be prevented from entering the oxide semiconductor layer as much as possible. Specifically, in the case where the oxide semiconductor layer 82b is an In-M-Zn oxide layer (M is Ga, Y, Zr, La, Ce, or Nd) and a target having the atomic ratio of metal elements of In:M:Zn=x₁:y₁:z₁ is used for forming the oxide semiconductor layer 82b, x₁/y₁ is preferably greater than or equal to 1/3 and less than or equal to 6, further preferably greater than or equal to 1 and less than or equal to 6, and z₁/y₁ is preferably greater than or equal to 1/3 and less than or equal to 6, further preferably greater than or equal to 1 and less than or equal to 6. Note that when z₁/y₁ is greater than or equal to 1 and less than or equal to 6, a CAAC-OS film to be described later as the oxide semiconductor layer 82b is easily formed. Typical examples of the atomic ratio of the metal elements of the target are In:M:Zn=1:1:1 and In:M:Zn=3:1:2.

Specifically, in the case where the oxide semiconductor layers 82a and 82c contain an In-M-Zn oxide (M is Ga, Y, Zr, La, Ce, or Nd), it is preferable that x₂/y₂<x₁/y₁ be satisfied and z₂/y₂ be greater than or equal to 1/3 and less than or equal to 6, further preferably greater than or equal to 1 and less than or equal to 6 when the atomic ratio of metal elements of In to M and Zn in a target for forming the oxide semiconductor layers 82a and 82c is x₂:y₂:z₂. Note that when z₂/y₂ is greater than or equal to 1 and less than or equal to 6, CAAC-OS films as the oxide semiconductor layers 82a and 82c are easily formed. Typical examples of the atomic ratio of metal elements of In to M and Zn in the target include 1:3:2, 1:3:4, 1:3:6, and 1:3:8.

The oxide semiconductor layers 82a and 82c each have a thickness greater than or equal to 3 nm and less than or equal to 100 nm, preferably greater than or equal to 3 nm and less than or equal to 50 nm. The thickness of the oxide semiconductor layer 82b is greater than or equal to 3 nm and less than or equal to 200 nm, preferably greater than or equal to 3 nm and less than or equal to 100 nm, further preferably greater than or equal to 3 nm and less than or equal to 50 nm.

The three oxide semiconductor layers (the oxide semiconductor layers 82a to 82c) can be either amorphous or crystalline. However, when the oxide semiconductor layer 82b where a channel region is formed is crystalline, the transistor 18 can have stable electrical characteristics; therefore, the oxide semiconductor layer 82b is preferably crystalline.

Note that a channel formation region refers to a region of the semiconductor layer of the transistor 18 that overlaps with the gate electrode and is located between the source electrode and the drain electrode. A channel region refers to a region through which current mainly flows in the channel formation region.

For example, when an In—Ga—Zn oxide film formed by a sputtering method is used as each of the oxide semiconductor layers 82a and 82c, the oxide semiconductor layers 82a and 82c can be deposited with the use of an In—Ga—Zn oxide target containing In, Ga, and Zn in an atomic ratio of 1:3:2. The deposition conditions can be as follows: an argon gas (flow rate: 30 sccm) and an oxygen gas (flow rate: 15 sccm) are used as the deposition gas; the pressure is 0.4 Pa; the substrate temperature is 200° C.; and the DC power is 0.5 kW.

Further, in the case where the oxide semiconductor layer 82b is a CAAC-OS film, the oxide semiconductor layer 82b is preferably deposited with the use of a polycrystalline target including an In—Ga—Zn oxide (In:Ga:Zn=1:1:1 in an atomic ratio). The deposition conditions can be as follows: an argon gas (flow rate: 30 sccm) and an oxygen gas (flow rate: 15 sccm) are used as the deposition gas; the pressure is 0.4 Pa; the substrate temperature is 300° C.; and the DC power is 0.5 kW.

There are few carrier generation sources in a highly purified oxide semiconductor (purified oxide semiconductor) obtained by reduction of impurities such as moisture and hydrogen serving as electron donors (donors) and reduction of oxygen vacancies; therefore, the highly purified oxide semiconductor can be an intrinsic (i-type) semiconductor or a substantially i-type semiconductor. For this reason, a transistor having a channel formation region in a highly purified oxide semiconductor layer has extremely low off-state current and high reliability. Thus, a transistor having a channel formation region in the oxide semiconductor layer easily has an electrical characteristic of positive threshold voltage (also referred to as a normally-off characteristic).

Specifically, various experiments can prove low off-state current of a transistor having a channel formation region in a highly purified oxide semiconductor layer. For example, even when an element has a channel width of 1×10⁶ μm and a channel length of 10 μm, off-state current can be less than or equal to the measurement limit of a semiconductor parameter analyzer, i.e., less than or equal to 1×10⁻¹³ A, at voltage (drain voltage) between the source electrode and the drain electrode of 1 V to 10 V. In that case, it can be seen that off-state current normalized on the channel width of the transistor is lower than or equal to 100 zA/μm. In addition, a capacitor and a transistor are connected to each other and the off-state current is measured with a circuit in which charge flowing into or from the capacitor is controlled by the transistor. In the measurement, a highly purified oxide semiconductor layer was used for a channel formation region of the transistor, and the off-state current of the transistor was measured from a change in the amount of charge in the capacitor per unit hour. As a result, it was found that, in the case where the voltage between the source electrode and the drain electrode of the transistor is 3 V, a lower off-state current of several tens of yA/μm is obtained. Accordingly, the off-state current of the transistor in which the purified oxide semiconductor layer is used as a channel formation region is considerably lower than that of a transistor in which silicon having crystallinity is used.

In the case where an oxide semiconductor is used for the semiconductor layer, at least indium (In) or zinc (Zn) is preferably included as an oxide semiconductor. As a stabilizer for reducing variation in electrical characteristics of a transistor using the oxide semiconductor, gallium (Ga) is preferably additionally contained. Tin (Sn) is preferably contained as a stabilizer. Hafnium (Hf) is preferably contained as a stabilizer. Aluminum (Al) is preferably contained as a stabilizer. Zirconium (Zr) is preferably contained as a stabilizer.

Among the oxide semiconductors, unlike silicon carbide, gallium nitride, or gallium oxide, an In—Ga—Zn oxide, an In—Sn—Zn oxide, or the like has an advantage of high mass productivity because a transistor with favorable electrical characteristics can be formed by sputtering or a wet process. Further, unlike silicon carbide, gallium nitride, or gallium oxide, with the use of the In—Ga—Zn oxide, a transistor with favorable electrical characteristics can be formed over a glass substrate. Further, a larger substrate can be used.

As another stabilizer, one or more kinds of lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu) may be contained.

As the oxide semiconductor, any of the following oxides can be used, for example: indium oxide, gallium oxide, tin oxide, zinc oxide, In—Zn oxide, Sn—Zn oxide, Al—Zn oxide, Zn—Mg oxide, Sn—Mg oxide, In—Mg oxide, In—Ga oxide, In—Ga—Zn oxide (also referred to as IGZO), In—Al—Zn oxide, In—Sn—Zn oxide, Sn—Ga—Zn oxide, Al—Ga—Zn oxide, Sn—Al—Zn oxide, In—Hf—Zn oxide, In—La—Zn oxide, In—Pr—Zn oxide, In—Nd—Zn oxide, In—Ce—Zn oxide, In—Sm—Zn oxide, In—Eu—Zn oxide, In—Gd—Zn oxide, In—Tb—Zn oxide, In—Dy—Zn oxide, In—Ho—Zn oxide, In—Er—Zn oxide, In—Tm—Zn oxide, In—Yb—Zn oxide, In—Lu—Zn oxide, In—Sn—Ga—Zn oxide, In—Hf—Ga—Zn oxide, In—Al—Ga—Zn oxide, In—Sn—Al—Zn oxide, In—Sn—Hf—Zn oxide, and In—Hf—Al—Zn oxide.

Note that, for example, an In—Ga—Zn oxide means an oxide containing In, Ga, and Zn and there is no particular limitation on the ratio of In:Ga:Zn. Further, the In—Ga—Zn oxide may contain a metal element other than In, Ga, and Zn. The In—Ga—Zn oxide has sufficiently high resistance when no electric field is applied thereto, so that off-state current can be sufficiently reduced. Further, the In—Ga—Zn oxide has high mobility.

For example, with an In—Sn—Zn oxide, high mobility can be realized relatively easily. However, even with an In—Ga—Zn oxide, mobility can be increased by reducing the defect density in the bulk.

Furthermore, in the transistor 18, a metal in the source electrode and the drain electrode might extract oxygen from the oxide semiconductor layer depending on a conductive material used for the source electrode and the drain electrode. In this case, regions of the oxide semiconductor layer in contact with the source electrode and the drain electrode become n-type regions due to the formation of oxygen vacancies. The n-type regions serve as a source region and a drain region, resulting in a decrease in the contact resistance between the oxide semiconductor layer and the source electrode and between the oxide semiconductor layer and the drain electrode. Accordingly, the formation of the n-type regions increases the mobility and on-state current of the transistor 18, achieving the high-speed operation of a semiconductor device using the transistor 18.

Note that the extraction of oxygen by a metal in the source electrode and the drain electrode is probably caused when the source electrode and the drain electrode are formed by a sputtering method or the like or when heat treatment is performed after the formation of the source electrode and the drain electrode. The n-type regions are more likely to be formed by forming the source electrode and the drain electrode with the use of a conductive material that is easily bonded to oxygen. Examples of such a conductive material include Al, Cr, Cu, Ta, Ti, Mo, and W.

Furthermore, in the case where the semiconductor layer including the stacked oxide semiconductor layers is used in the transistor 18, the regions having n-type conductivity preferably extend to the oxide semiconductor layer 82b serving as a channel region in order that the mobility and on-state current of the transistor 18 can be further increased and the semiconductor device can operate at higher speed.

The insulating layer 81 preferably has a function of supplying part of oxygen to the oxide semiconductor layers 82a to 82c by heating. It is preferable that the number of defects in the insulating layer 81 be small, and typically the spin density of g=2.001 due to a dangling bond of silicon be lower than or equal to 1×10¹⁸ spins/cm³. The spin density is measured by ESR spectroscopy.

The insulating layer 81, which has a function of supplying part of the oxygen to the oxide semiconductor layers 82a to 82c by heating, is preferably an oxide. Examples of the oxide include aluminum oxide, magnesium oxide, silicon oxide, silicon oxynitride, silicon nitride oxide, gallium oxide, germanium oxide, yttrium oxide, zirconium oxide, lanthanum oxide, neodymium oxide, hafnium oxide, and tantalum oxide. The insulating layer 81 can be formed by a plasma chemical vapor deposition (CVD) method, a sputtering method, or the like.

Note that in this specification, oxynitride contains more oxygen than nitrogen, and nitride oxide contains more nitrogen than oxygen.

Note that in the transistor 18 illustrated in FIGS. 12A to 12C and FIGS. 13A to 13C, the conductive layer 86 overlaps with end portions of the oxide semiconductor layer 82b including a channel region that do not overlap with the conductive layers 83 and 84, i.e., end portions of the oxide semiconductor layer 82b that are in a region different from a region where the conductive layers 83 and 84 are located. When the end portions of the oxide semiconductor layer 82b are exposed to plasma by etching for forming the end portions, chlorine radical, fluorine radical, or the like generated from an etching gas is easily bonded to a metal element contained in the oxide semiconductor. For this reason, in the end portions of the oxide semiconductor layer, oxygen bonded to the metal element is easily eliminated, so that an oxygen vacancy is easily formed; thus, the oxide semiconductor layer easily has n-type conductivity. However, an electric field applied to the end portions can be adjusted by controlling the potential of the conductive layer 86 because the end portions of the oxide semiconductor layer 82b that do not overlap with the conductive layers 83 and 84 overlap with the conductive layer 86 in the transistor 18 illustrated in FIGS. 12A to 12C and FIGS. 13A to 13C. Consequently, the flow of current between the conductive layers 83 and 84 through the end portions of the oxide semiconductor layer 82b can be controlled by the potential supplied to the conductive layer 86. Such a structure of the transistor 18 is referred to as a surrounded channel (s-channel) structure.

With the s-channel structure, specifically, when a potential at which the transistor 18 is turned off is supplied to the conductive layer 86, the amount of off-state current that flows between the conductive layers 83 and 84 through the end portions of the oxide semiconductor layer 82b can be reduced. For this reason, in the transistor 18, even when the distance between the conductive layers 83 and 84 at the end portions of the oxide semiconductor layer 82b is reduced as a result of reducing the channel length to obtain high on-state current, the transistor 18 can have low off-state current. Consequently, with the short channel length, the transistor 18 can have high on-state current when in an on state and low off-state current when in an off state.

With the s-channel structure, specifically, when a potential at which the transistor 18 is turned on is supplied to the conductive layer 86, the amount of current that flows between the conductive layers 83 and 84 through the end portions of the oxide semiconductor layer 82b can be increased. The current contributes to an increase in the field-effect mobility and an increase in on-state current of the transistor 18. When the end portions of the oxide semiconductor layer 82b overlap with the conductive layer 86, carriers flow in a wide region of the oxide semiconductor layer 82b as well as in a region in the vicinity of the interface between the oxide semiconductor layer 82b and the insulating layer 85, which results in an increase in the amount of carrier movement in the transistor 18. As a result, the on-state current of the transistor 18 is increased, and the field-effect mobility is increased to 10 cm²N·s or higher or to 20 cm²N·s or higher, for example. Note that here, the field-effect mobility is not an approximate value of the mobility as the physical property of the oxide semiconductor layer but is an index of current drive capability and the apparent field-effect mobility of a saturation region of the transistor.

A structure of the oxide semiconductor layer is described below.

An oxide semiconductor layer is classified roughly into a single crystal oxide semiconductor layer and a non-single-crystal oxide semiconductor layer. The non-single-crystal oxide semiconductor layer includes any of an amorphous oxide semiconductor layer, a microcrystalline oxide semiconductor layer, a polycrystalline oxide semiconductor layer, a c-axis aligned crystalline oxide semiconductor (CAAC-OS) film, and the like.

The amorphous oxide semiconductor layer has disordered atomic arrangement and no crystalline component. A typical example thereof is an oxide semiconductor layer in which no crystal part exists even in a microscopic region, and the whole of the layer is amorphous.

The microcrystalline oxide semiconductor layer includes a microcrystal (also referred to as nanocrystal) with a size greater than or equal to 1 nm and less than 10 nm, for example. Thus, the microcrystalline oxide semiconductor layer has a higher degree of atomic order than the amorphous oxide semiconductor layer. Hence, the density of defect states of the microcrystalline oxide semiconductor layer is lower than that of the amorphous oxide semiconductor layer.

The CAAC-OS film is one of oxide semiconductor layers including a plurality of crystal parts, and most of the crystal parts each fit inside a cube whose one side is less than 100 nm. Thus, there is a case where a crystal part included in the CAAC-OS film fits inside a cube whose one side is less than 10 nm, less than 5 nm, or less than 3 nm. The density of defect states of the CAAC-OS film is lower than that of the microcrystalline oxide semiconductor layer. In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

In the cross-sectional TEM image of the CAAC-OS film observed in a direction substantially parallel to the sample surface, metal atoms arranged in a layered manner are seen in the crystal parts. Each metal atom layer has a shape that reflects a surface over which the CAAC-OS film is formed (hereinafter, a surface over which the CAAC-OS film is formed is referred to as a formation surface) or a top surface of the CAAC-OS film, and is arranged parallel to the formation surface or the top surface of the CAAC-OS film.

In this specification, the term “parallel” indicates that the angle formed between two straight lines is greater than or equal to −10° and less than or equal to 10°, and accordingly also includes the case where the angle is greater than or equal to −5° and less than or equal to 5°. The term “perpendicular” indicates that the angle formed between two straight lines is greater than or equal to 80° and less than or equal to 100°, and accordingly also includes the case where the angle is greater than or equal to 85° and less than or equal to 95°.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM observation and the plan-view TEM observation, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single crystal oxide semiconductor layer of InGaZnO₄, six peaks appear. The six peaks are derived from crystal planes equivalent to the (110) plane. On the other hand, in the case of a CAAC-OS film, a peak is not clearly observed even when φ scan is performed with 2θ fixed at around 56°.

According to the above results, in the CAAC-OS film having c-axis alignment, while the directions of a-axes and b-axes are irregularly oriented between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal part is formed concurrently with deposition of the CAAC-OS film or is formed through crystallization treatment such as heat treatment. As described above, the c-axis of the crystal is aligned in a direction parallel to a normal vector of a formation surface or a normal vector of a top surface of the CAAC-OS film. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of crystallinity in the vicinity of the top surface is higher than that in the vicinity of the formation surface in some cases. Further, when an impurity is added to the CAAC-OS film, the degree of crystallinity in a region to which the impurity is added is changed, and the degree of crystallinity in the CAAC-OS film varies depending on regions.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appear at around 31° and a peak of 2θ not appear at around 36°.

In a transistor including the CAAC-OS film, a change in electrical characteristics due to irradiation with visible light or ultraviolet light is small. Thus, the transistor has high reliability.

Note that an oxide semiconductor layer may be a stacked film including two or more kinds of an amorphous oxide semiconductor layer, a microcrystalline oxide semiconductor layer, and a CAAC-OS film, for example.

For the deposition of the CAAC-OS film, the following conditions are preferably used.

By reducing the amount of impurities entering the CAAC-OS film during the deposition, the crystal state can be prevented from being broken by the impurities. For example, the concentration of impurities (e.g., hydrogen, water, carbon dioxide, and nitrogen) that exist in the treatment chamber may be reduced. Furthermore, the concentration of impurities in a deposition gas may be reduced. Specifically, a deposition gas whose dew point is −80° C. or lower, preferably −100° C. or lower is used.

By increasing the substrate heating temperature during the deposition, migration of a sputtered particle is likely to occur after the sputtered particle reaches a substrate surface. Specifically, the substrate heating temperature during the deposition is higher than or equal to 100° C. and lower than or equal to 740° C., preferably higher than or equal to 200° C. and lower than or equal to 500° C. By increasing the substrate heating temperature during the deposition, when the flat-plate-like or pellet-like sputtered particle reaches the substrate, migration occurs on the substrate surface, so that a flat plane of the sputtered particles is attached to the substrate.

Furthermore, it is preferable that the proportion of oxygen in the deposition gas be increased and the power be optimized in order to reduce plasma damage at the deposition. The proportion of oxygen in the deposition gas is higher than or equal to 30 vol %, preferably 100 vol %.

As an example of the target, an In—Ga—Zn oxide target is described below.

The In—Ga—Zn oxide target, which is polycrystalline, is made in the following manner: InO_{X} powder, GaO_{Y} powder, and ZnO_{Z} powder are mixed in a predetermined molar ratio, pressure is applied to the mixture, and heat treatment is performed at a temperature higher than or equal to 1000° C. and lower than or equal to 1500° C. Note that X, Y, and Z are each a given positive number. Here, the predetermined molar ratio of InO_{X} powder to GaO_{Y} powder and ZnO_{Z} powder is, for example, 2:2:1, 8:4:3, 3:1:1, 1:1:1, 4:2:3, 4:2:4.1, or 3:1:2. The kinds of powder and the molar ratio for mixing powder may be determined as appropriate depending on the desired target.

An alkali metal is not an element included in an oxide semiconductor and thus is an impurity. Also, alkaline earth metal is an impurity in the case where the alkaline earth metal is not a component of the oxide semiconductor. Alkali metal, in particular, Na becomes Na when an insulating layer in contact with the oxide semiconductor layer is an oxide and Na diffuses into the insulating layer. Further, in the oxide semiconductor layer, Na cuts or enters a bond between metal and oxygen that are included in the oxide semiconductor. As a result, for example, degradation of electrical characteristics of a transistor, such as a normally-on state of the transistor due to shift of the threshold voltage in the negative direction or reduction in mobility, occurs. In addition, variations in electrical characteristics also occur. Specifically, the Na concentration according to secondary ion mass spectrometry is reduced to preferably less than or equal to 5×10¹⁶/cm³, further preferably less than or equal to 1×10¹⁶/cm³, still further preferably less than or equal to 1×10¹⁵/cm³. In a similar manner, the measurement value of Li concentration is preferably less than or equal to 5×10¹⁵/cm³, further preferably less than or equal to 1×10¹⁵/cm³. In a similar manner, the measurement value of K concentration is preferably less than or equal to 5×10¹⁵/cm³, further preferably less than or equal to 1×10¹⁵/cm³.

In the case where a metal oxide containing indium is used, silicon or carbon having higher bond energy with oxygen than indium might cut the bond between indium and oxygen, so that an oxygen vacancy is formed. Accordingly, when silicon or carbon is contained in the oxide semiconductor layer, the electrical characteristics of the transistor are likely to deteriorate as in the case of using an alkali metal or an alkaline earth metal. Thus, the concentration of silicon and the concentration of carbon in the oxide semiconductor layer are preferably low. Specifically, the carbon concentration or the silicon concentration measured by secondary ion mass spectrometry is preferably less than or equal to 1×10¹⁸/cm³. In that case, the deterioration of the electrical characteristics of the transistor can be prevented, so that the reliability of the semiconductor device can be improved.

The structure described above in this embodiment can be used in appropriate combination with any of the structures described in the other embodiments.

### Embodiment 4

In this embodiment, an example of a chip including the semiconductor device of one embodiment of the present invention and an example of a module of an electronic device will be described.

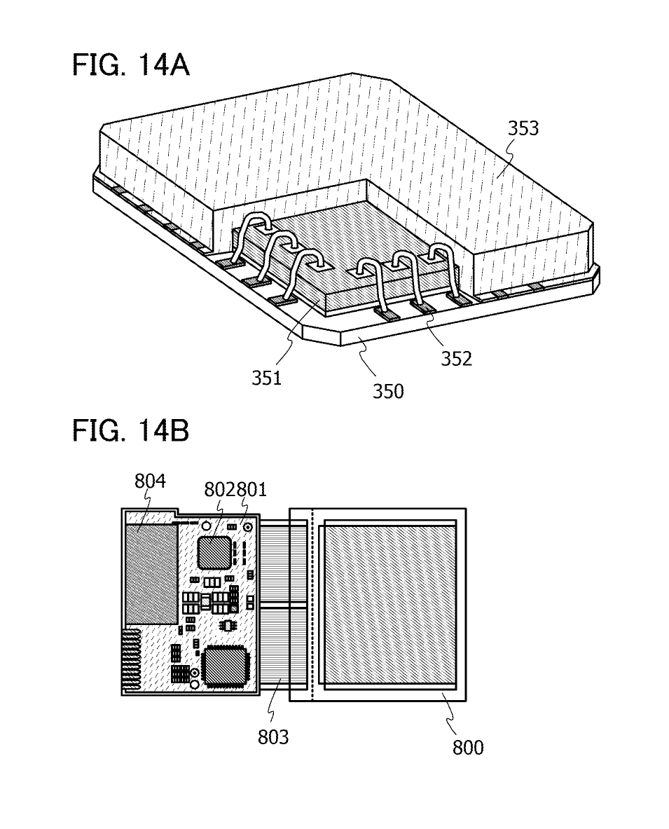

FIG. 14A is a perspective view illustrating a cross-sectional structure of a package using a lead frame interposer.

In the package illustrated in FIG. 14A, a chip 351 corresponding to the semiconductor device of one embodiment of the present invention is connected to a terminal 352 over an interposer 350 by a wire bonding method. The terminal 352 is placed on a surface of the interposer 350 on which the chip 351 is mounted. The chip 351 can be sealed by a mold resin 353, in which case the chip 351 is sealed so that part of each of the terminals 352 is exposed.

FIG. 14B illustrates the structure of a module of an electronic device in which the package is mounted on a circuit board.

In the module of a mobile phone illustrated in FIG. 14B, a package 802 and a battery 804 are mounted on a printed wiring board 801. In addition, the printed wiring board 801 is mounted on a panel 800 including a display element by an FPC 803.

The structure described above in this embodiment can be used in appropriate combination with any of the structures described in the other embodiments.

### Embodiment 5

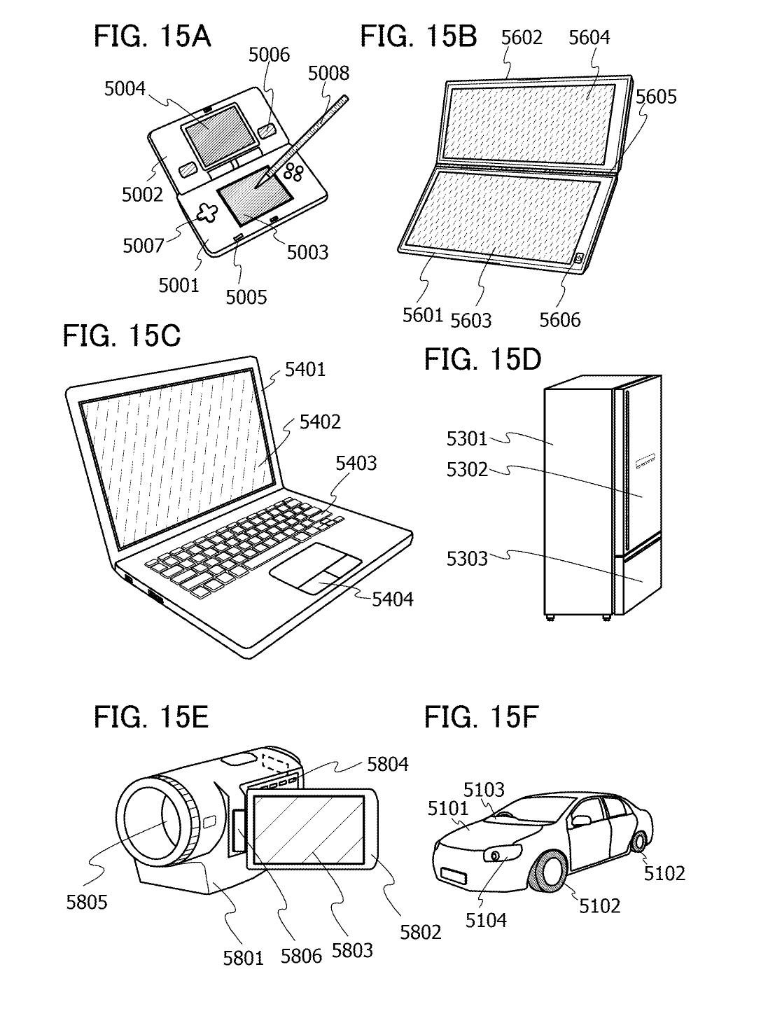

The semiconductor device of one embodiment of the present invention can be used for display devices, personal computers, and image reproducing devices provided with recording media (typically, devices that reproduce the content of recording media such as digital versatile discs (DVDs) and have displays for displaying the reproduced images). Other examples of electronic devices that can include the semiconductor device of one embodiment of the present invention are mobile phones, game machines including portable game machines, portable information terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. Specific examples of these electronic devices are illustrated in FIGS. 15A to 15F.

FIG. 15A illustrates a portable game machine, which includes a housing 5001, a housing 5002, a display portion 5003, a display portion 5004, a microphone 5005, speakers 5006, a control key 5007, a stylus 5008, and the like. The semiconductor device of one embodiment of the present invention can be used for a variety of integrated circuits included in the portable game machine. Note that although the portable game machine in FIG. 15A includes the two display portions 5003 and 5004, the number of display portions included in the portable game machine is not limited to two.

FIG. 15B illustrates a portable information terminal, which includes a first housing 5601, a second housing 5602, a first display portion 5603, a second display portion 5604, a joint 5605, an operation key 5606, and the like. The first display portion 5603 is provided in the first housing 5601, and the second display portion 5604 is provided in the second housing 5602. The first housing 5601 and the second housing 5602 are connected to each other with the joint 5605, and the angle between the first housing 5601 and the second housing 5602 can be changed with the joint 5605. An image on the first display portion 5603 may be switched depending on the angle between the first housing 5601 and the second housing 5602 at the joint 5605. The semiconductor device of one embodiment of the present invention can be used for a variety of integrated circuits included in the portable information terminal. A display device with a position input function may be used as at least one of the first display portion 5603 and the second display portion 5604. Note that the position input function can be added by providing a touch panel in a display device. Alternatively, the position input function can be added by providing a photoelectric conversion element called a photosensor in a pixel portion of a display device.

FIG. 15C illustrates a notebook personal computer, which includes a housing 5401, a display portion 5402, a keyboard 5403, a pointing device 5404, and the like. The semiconductor device of one embodiment of the present invention can be used for a variety of integrated circuits included in the notebook personal computer.

FIG. 15D illustrates an electric refrigerator-freezer, which includes a housing 5301, a door for a refrigerator 5302, a door for a freezer 5303, and the like. The semiconductor device of one embodiment of the present invention can be used for a variety of integrated circuits included in the electric refrigerator-freezer.

FIG. 15E illustrates a video camera, which includes a first housing 5801, a second housing 5802, a display portion 5803, operation keys 5804, a lens 5805, a joint 5806, and the like. The operation keys 5804 and the lens 5805 are provided for the first housing 5801, and the display portion 5803 is provided for the second housing 5802. The semiconductor device of one embodiment of the present invention can be used for a variety of integrated circuits included in the video camera. The first housing 5801 and the second housing 5802 are connected to each other with the joint 5806, and the angle between the first housing 5801 and the second housing 5802 can be changed with the joint 5806. Images displayed on the display portion 5803 may be switched in accordance with the angle at the joint 5806 between the first housing 5801 and the second housing 5802.

FIG. 15F illustrates a motor vehicle, which includes a car body 5101, wheels 5102, a dashboard 5103, lights 5104, and the like. The semiconductor device of one embodiment of the present invention can be used for a variety of integrated circuits included in the motor vehicle.

This application is based on Japanese Patent Application serial no. 2014-138493 filed with Japan Patent Office on Jul. 4, 2014, the entire contents of which are hereby incorporated by reference.

What is claimed is:

1. A semiconductor device executing a pipeline processing, comprising:
an instruction decode stage comprising a decoder; and
an execution stage comprising a first arithmetic portion and a second arithmetic portion,
the first arithmetic portion comprising a first arithmetic unit and a first transistor that is connected to the first arithmetic unit and is provided between wirings through which power supply voltage is supplied to the first arithmetic unit, wherein supply of the power supply voltage to the first arithmetic unit depends on an on/off state of the first transistor,
the second arithmetic portion comprising a second arithmetic unit and a second transistor that is connected to the second arithmetic unit and is provided between the wirings through which the power supply voltage is supplied to the second arithmetic unit, wherein supply of the power supply voltage to the second arithmetic unit depends on an on/off state of the second transistor,
wherein the on/off state of each of the first transistor and the second transistor is controlled according to an instruction that is decoded in the decoder and supplied to a gate of each of the first transistor and the second transistor.

2. The semiconductor device according to claim 1, wherein a channel formation region of each of the first transistor and the second transistor comprises an oxide semiconductor.

3. The semiconductor device according to claim 2, wherein the oxide semiconductor comprises In, Ga, and Zn.

4. The semiconductor device according to claim 1, wherein the first transistor and the second transistor are respectively provided over the first arithmetic unit and the second arithmetic unit with an insulating layer provided therebetween.

5. The semiconductor device according to claim 1, wherein the first arithmetic unit is designed to execute an instruction for addition and subtraction, and the second arithmetic unit is designed to execute an instruction for multiplication.

6. The semiconductor device according to claim 1,
wherein the first arithmetic unit comprises an inverter and a p-channel transistor,
wherein the gate of the first transistor is electrically connected to a gate of the p-channel transistor, and
wherein one of a source and a drain of the p-channel transistor is electrically connected to an output terminal of the inverter.

7. An electronic device comprising:
the semiconductor device according to claim 1; and
a display device or a speaker.

8. A semiconductor device executing a pipeline processing, comprising:
an instruction decode stage comprising a decoder; and
an execution stage comprising a first arithmetic portion and a second arithmetic portion,
the first arithmetic portion comprising a first arithmetic unit and a first transistor that is connected to the first arithmetic unit and is provided between wirings through which power supply voltage is supplied to the first arithmetic unit, wherein supply of the power supply voltage to the first arithmetic unit depends on an on/off state of the first transistor,
the second arithmetic portion comprising a second arithmetic unit and a second transistor that is connected to the second arithmetic unit and is provided between the wirings through which the power supply voltage is supplied to the second arithmetic unit, wherein supply of the power supply voltage to the second arithmetic unit depends on an on/off state of the second transistor,
wherein the on/off state of each of the first transistor and the second transistor is controlled according to an instruction that is decoded in the decoder and supplied to a gate of each of the first transistor and the second transistor,
wherein the first arithmetic unit and the second arithmetic unit each comprises a third transistor, and
wherein the first transistor and the second transistor are provided in a different layer from a layer in which the third transistor is provided.

9. The semiconductor device according to claim 8, wherein a channel formation region of each of the first transistor and the second transistor comprises an oxide semiconductor.

10. The semiconductor device according to claim 9, wherein the oxide semiconductor comprises In, Ga, and Zn.

11. The semiconductor device according to claim 8, wherein a channel formation region of the third transistor comprises silicon.

12. The semiconductor device according to claim 8, wherein a source electrode or a drain electrode of the third transistor has a region overlapping with a source electrode or a drain electrode of the first transistor or the second transistor.

13. The semiconductor device according to claim 8, wherein the first transistor and the second transistor are respectively provided over the first arithmetic unit and the second arithmetic unit with an insulating layer provided therebetween.

14. The semiconductor device according to claim 8, wherein the first arithmetic unit is designed to execute an instruction for addition and subtraction, and the second arithmetic unit is designed to execute an instruction for multiplication.

15. The semiconductor device according to claim 8,
wherein the first arithmetic unit comprises an inverter and a p-channel transistor,
wherein the gate of the first transistor is electrically connected to a gate of the p-channel transistor, and
wherein one of a source and a drain of the p-channel transistor is electrically connected to an output terminal of the inverter.

16. An electronic device comprising:
the semiconductor device according to claim 8; and
a display device or a speaker.
